(19) United States
(12) Patent Application Publication
(10) Pub. No.: US 2026/0090387 A1
(43) Pub. Date: Mar. 26, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jongpa HONG, Suwon-si (KR); Yeongkwon KO, Suwon-si (KR); Keumhee MA, Suwon-si (KR); Gunho CHANG, Suwon-si (KR); Youngbae KIM, Suwon-si (KR)

(73) Assignee: SAMSUNG ELECTRONICS CO., LTD., Suwon-si (KR)

(21) Appl. No.: 19/209,388

(22) Filed: May 15, 2025

(30) Foreign Application Priority Data
Sep. 25, 2024 (KR) 10-2024-0129684

(51) Int. Cl. H01L 23/00; H01L 23/31; H01L 23/48; H01L 25/16

(52) U.S. Cl. CPC H10W 42/121; H10W 20/20; H10W 74/111; H10W 90/00; H10W 74/15; H10W 90/297; H10W 90/722; H10W 90/732

(57) ABSTRACT

A semiconductor package includes: a base chip; a first semiconductor chip disposed on the base chip, and including a first semiconductor substrate; one or more second semiconductor chips on the first semiconductor chip, and respectively including a second semiconductor substrate, wherein each of the first and second semiconductor substrates includes a device region and an edge region; first connection bumps disposed to overlap the device region; a first edge structure disposed to overlap the edge region; second connection bumps disposed to overlap the device region; a second edge structure disposed to overlap the edge region; a first adhesive layer disposed on the first semiconductor chip and surrounding the first connection bumps and the first edge structure; and a second adhesive layer disposed on the each of the one or more second semiconductor chips and surrounding the second connection bumps and the second edge structure.

### CROSS-REFERENCE TO RELATED APPLICATION(S)

This application claims benefit of priority to Korean Patent Application No. 10-2024-0129684 filed on Sep. 25, 2024, in the Korean Intellectual Property Office, the disclosure of which is incorporated herein by reference in its entirety.

### BACKGROUND

The present disclosure relates to a semiconductor package and a method of manufacturing the same.

With the implementation of lightweightedness and high performance of electronic devices, development of miniaturized and high performance semiconductor packages is required in a semiconductor package field. In order to implement miniaturization and high performance of semiconductor packages, research and development of semiconductor packages including edge structures disposed in edge regions have been continuously conducted.

### SUMMARY

An aspect of the present disclosure is to provide a semiconductor package including an edge structure disposed in an edge region and a method of manufacturing the same.

As a means of addressing the above-described aspect, an example embodiment of the present disclosure provides a semiconductor package comprising: a base chip comprising upper pads on an upper surface of the base chip; a first semiconductor chip on the base chip, and the first semiconductor chip comprising a first semiconductor substrate, first rear pads disposed on a rear surface thereof, and first front pads disposed on a front surface thereof; one or more second semiconductor chips stacked on the first semiconductor chip, and respectively comprising a second semiconductor substrate, second rear pads disposed on a rear surface thereof, and second front pads disposed on a front surface thereof, wherein each of the first and second semiconductor substrates comprises a device region and an edge region surrounding the device region, and the upper pads, the first and second rear pads and the first and second front pads overlap the device region; first connection bumps disposed to overlap the device region in a lower portion of the first semiconductor chip, and electrically connecting the first rear pads and the upper pads; a first edge structure disposed to overlap the edge region in the lower portion of the first semiconductor chip; second connection bumps disposed to overlap the device region in lower portions of each of the one or more second semiconductor chips, and electrically connecting pads facing each other among the first rear pads, the second front pads, and the second rear pads; a second edge structure disposed to overlap the edge region in the lower portions of each of the one or more second semiconductor chips; a first adhesive layer disposed on the front surface of the first semiconductor chip and surrounding the first connection bumps and the first edge structure; and a second adhesive layer disposed on the front surface of each of the one or more second semiconductor chips and surrounding the second connection bumps and the second edge structure. Each of the first and second edge structures comprises a material having a thermal expansion coefficient lower than a thermal expansion coefficient of the first adhesive layer and a thermal expansion coefficient of the second adhesive layer.

Additionally, provided is a semiconductor package comprising: a base chip; a first semiconductor chip on the base chip, and the first semiconductor chip comprising a first semiconductor substrate and a first passivation layer on the first semiconductor substrate; a second semiconductor chip on the first semiconductor chip, the second semiconductor chip comprising a second semiconductor substrate and a second passivation layer on the second semiconductor substrate; wherein each of the first and second semiconductor substrates comprises: a device region; a first edge region surrounding the device region; and a second edge region surrounding the first edge region; a guard ring structure comprising a plurality of guard ring pattern layers stacked on the first edge region in a vertical direction; a crack blocking structure comprising a plurality of blocking pattern layers stacked on the second edge region in the vertical direction; first connection bumps disposed to overlap the device region in a lower portion of the first passivation layer of the first semiconductor chip, and electrically connecting the base chip and the first semiconductor chip; second connection bumps disposed to overlap the device region in a lower portion of the second passivation layer of the second semiconductor chip, and electrically connecting the first and second semiconductor chips; a first edge structure disposed to overlap the second edge region in the lower portion of the first passivation layer of the first semiconductor chip; a second edge structure disposed to overlap the second edge region in the lower portion of the second passivation layer of the second semiconductor chip; and adhesive layers comprising a first adhesive layer surrounding the first connection bumps and the first edge structure on the first passivation layer, and a second adhesive layer surrounding the second connection bumps and the second edge structure on the second passivation layer.

Additionally, provided is a semiconductor package comprising: a base chip comprising first-first and first-second upper pads disposed on an upper surface thereof; a first semiconductor chip disposed on the base chip, and comprising a first semiconductor substrate and a first passivation layer on the first semiconductor substrate, wherein the first semiconductor chip has first-first and first-second rear pads disposed on a first rear surface thereof, and first-first and first-second front pads disposed on a first front surface thereof; one or more second semiconductor chips stacked on the first semiconductor chip, and respectively comprising a second semiconductor substrate and a second passivation layer on the second semiconductor substrate, wherein each of the one or more second semiconductor chips has second-first and second-second rear pads disposed on a second rear surface thereof, and second-first and second-second front pads disposed on a second front surface thereof. Each of the first and second semiconductor substrates comprises: a device region; a first edge region surrounding the device region and having a guard ring structure disposed thereon; and a second edge region surrounding the first edge region and having a crack blocking structure disposed therein, the first-first upper pads, the first-first and second-first rear pads, and the first-first and second-first front pads overlap the device region, and the first-second upper pads, the first-second and second-second rear pads, and the first-second and second-second front pads overlap the second edge region; first-first connection bumps disposed to overlap the device region in a lower portion of the first passivation layer of the first semiconductor chip, and electrically connecting the first-first upper pads and the first-first rear pads facing each other; first-second connection bumps disposed to overlap the second edge region in the lower portion of the first passivation layer of the first semiconductor chip, and connecting the first-second upper pads and the first-second rear pads facing each other; second-first connection bumps disposed to overlap the device region in a lower portion of the second passivation layer of the one or more second semiconductor chips, and connecting the first-first rear pads and the second-first front pads facing each other; second-second connection bumps disposed to overlap the second edge region in the lower portion of the second passivation layer of the one or more second semiconductor chips and connecting the first-second rear pads and the second-second front pads facing each other; and adhesive layers comprising a first adhesive layer surrounding the first-first and first-second connection bumps on the first passivation layer, and a second adhesive layer surrounding the second-first and second-second connection bumps on the second passivation layer.

According to example embodiments of the technical concept of the present disclosure, a semiconductor package including an edge structure disposed in an edge region and a method for manufacturing the same are provided.

Specifically, in a semiconductor package according to the present disclosure, an edge structure having a thermal expansion coefficient lower than a thermal expansion coefficient of an adhesive layer may be included in an edge region surrounding a device region, thereby minimizing or preventing the influence of a propagating crack.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor package according to an example embodiment;

FIG. 2 is a cross-sectional view of a semiconductor package taken along line I-I′ of FIG. 1;

FIG. 3A is a partially enlarged view illustrating region ‘A’ of FIG. 2;

FIG. 3B is a partially enlarged view illustrating region ‘B’ of FIG. 3A;

FIG. 3C is a plan view illustrating the semiconductor package of FIG. 3A;

FIG. 4 is a plan view illustrating a semiconductor package according to an example embodiment;

FIG. 5A is a partially enlarged view of a semiconductor package according to an example embodiment;

FIG. 5B is a plan view illustrating the semiconductor package of FIG. 5A;

FIG. 6A is a partially enlarged view of a semiconductor package according to an example embodiment;

FIG. 6B is a partially enlarged view illustrating region ‘C’ of FIG. 6A;

FIG. 6C is a plan view illustrating the semiconductor package of FIG. 6A;

FIG. 7A is a partially enlarged view of a semiconductor package according to an example embodiment;

FIG. 7B is a plan view illustrating the semiconductor package of FIG. 7A;

FIG. 8 is a partially enlarged view of a semiconductor package according to an example embodiment;

FIG. 9 is a partially enlarged view of a semiconductor package according to an example embodiment;

FIG. 10 is a partially enlarged view of a semiconductor package according to an example embodiment;

FIG. 11 is a partially enlarged view of a semiconductor package according to an example embodiment;

FIG. 12 is a partially enlarged view of a semiconductor package according to an example embodiment;

FIG. 13 is a partially enlarged view of a semiconductor package according to an example embodiment;

FIG. 14 is a cross-sectional view of a semiconductor package taken along line I-I′ of FIG. 1;

FIG. 15 is a plan view illustrating a semiconductor package according to an example embodiment;

FIG. 16 is a cross-sectional view of a semiconductor package taken along line II-II′ of FIG. 15; and

FIGS. 17 to 23 are cross-sectional views illustrating a method of manufacturing a semiconductor package according to an example embodiment of the present disclosure according to a process order.

### DETAILED DESCRIPTION

Hereinafter, the terms ‘above,’ ‘upper portion,’ ‘upper surface,’ ‘below’, ‘lower portion,’ ‘lower surface,’ ‘side surface,’ ‘upper end,’ ‘lower end,’ and the like, may be understood as being indicated based on the drawing, except that they are indicated by drawing references and referred to separately. The terms “upper,” “intermediate,” “lower”, and the like, may be replaced with other terms, such as “first,” “second,” and “third,” and used to describe components of the specification. The terms “first,” “second,” and “third” may be used to describe various components, but the components are not limited by the terms, and the “first component” may be termed the “second component.”

Hereinafter, example embodiments of the present disclosure will be described with reference to the accompanying drawings.

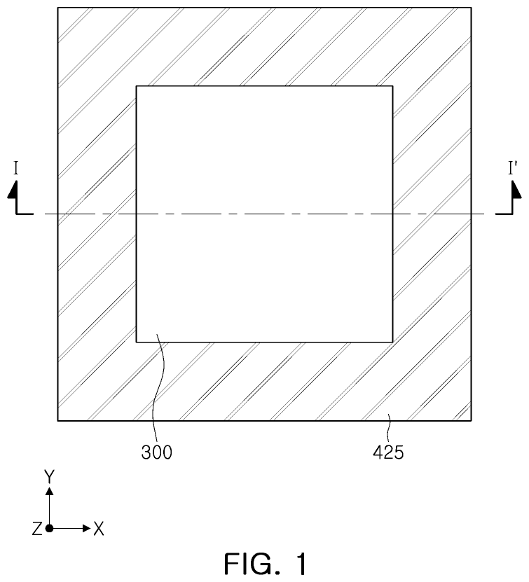

FIG. 1 is a plan view illustrating a semiconductor package according to an example embodiment.

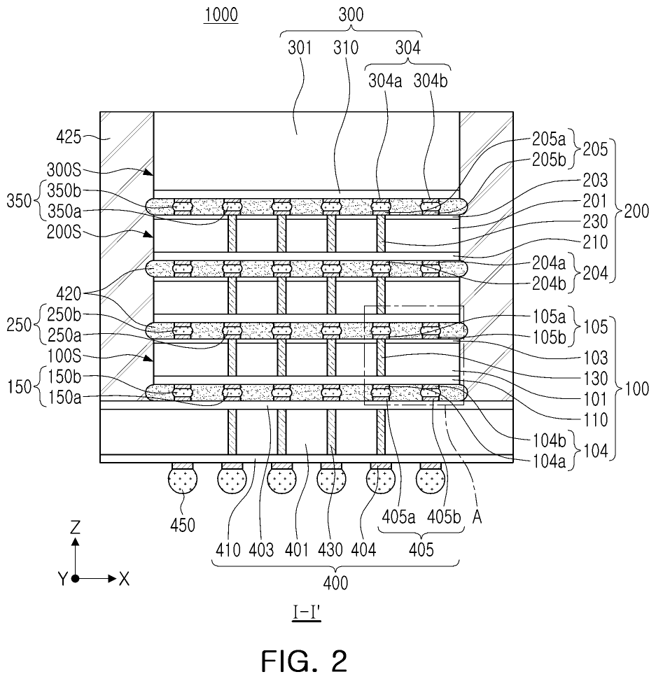

FIG. 2 is a cross-sectional view of a semiconductor package taken along line I-I′ of FIG. 1.

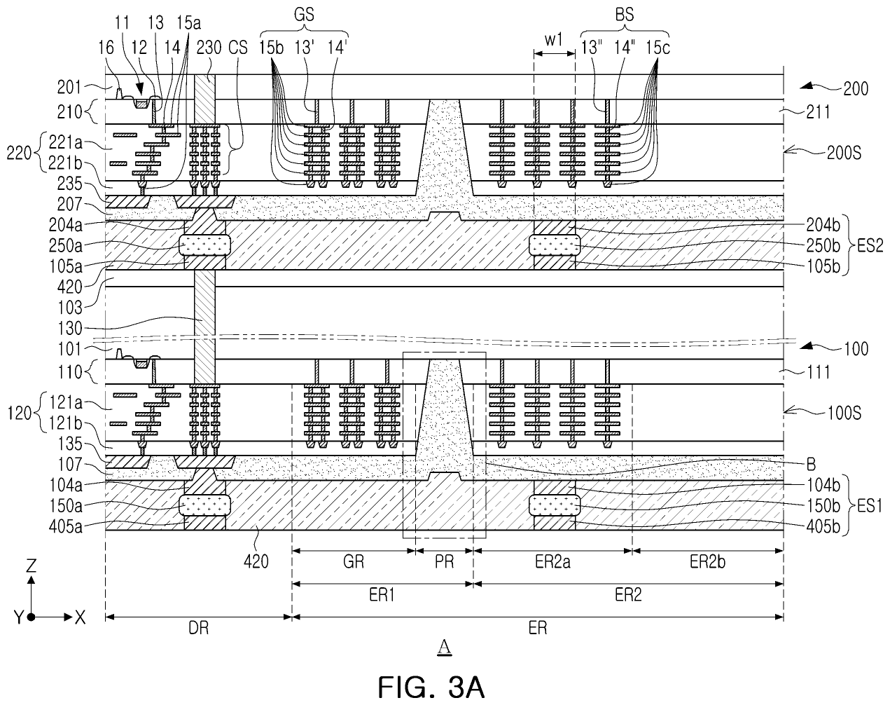

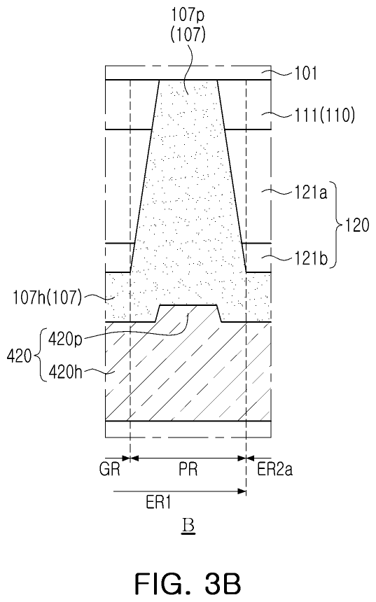

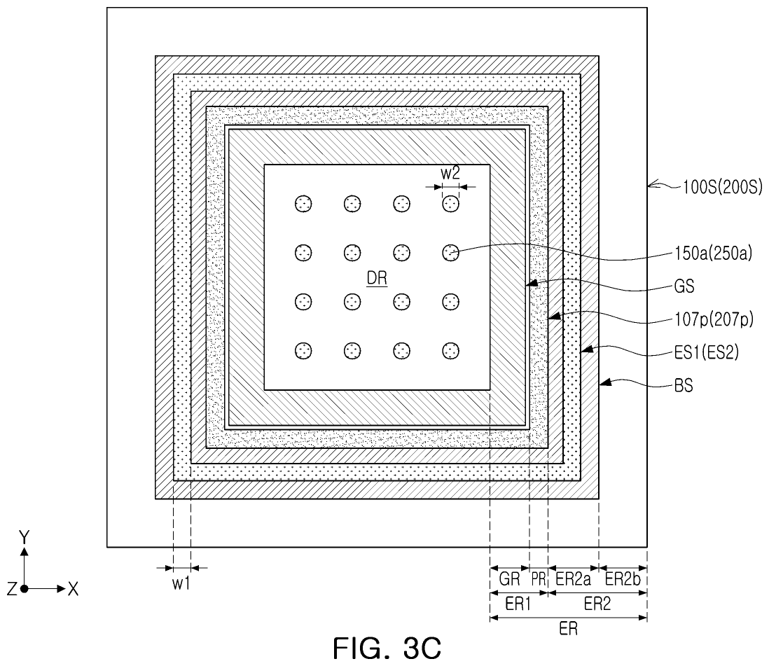

FIG. 3A is a partially enlarged view illustrating region ‘A’ of FIG. 2, and FIG. 3B is a partially enlarged view of region ‘B’ of FIG. 3A. FIG. 3C may be a plan view illustrating only some components of the semiconductor package of FIG. 3A to describe an arrangement relationship between the first and second edge structures ES1 and ES2.

Referring to FIGS. 1, 2, 3A, 3B and 3C, a semiconductor package 1000 of an example embodiment may include a plurality of semiconductor chips 100, 200 and 300 on a base chip 400, connection bumps 150, 250 and 350, at least one adhesive layer 420, and an encapsulant 425.

The plurality of semiconductor chips 100, 200 and 300 may be formed of memory chips or memory devices for storing or outputting data based on address commands and control commands received from the base chip 400. For example, the plurality of semiconductor chips 100, 200 and 300 may include volatile memory devices such as DRAM and SRAM, or nonvolatile memory devices such as PRAM, MRAM, FeRAM or RRAM. Among the plurality of semiconductor chips 100, 200 and 300, an uppermost semiconductor chip 300 (hereinafter, “third semiconductor chip”) might not include a through-via, and a rear surface thereof may be exposed from the encapsulant 425, but the present disclosure is not limited thereto.

The plurality of semiconductor chips 100, 200 and 300 may include a first semiconductor chip 100, at least one second semiconductor chip 200, and a third semiconductor chip 300, which are sequentially stacked on the base chip 400.

The base chip 400 may include a substrate 401, an upper protection layer 403, upper pads 405 and lower pads 404, a device layer 410, and through-electrodes 430. The base chip 400 may be, for example, a buffer chip including a plurality of logic devices and/or a plurality of memory devices in the device layer 410. Accordingly, the base chip 400 may transmit signals from the plurality of semiconductor chips 100, 200 and 300 that are stacked on an upper portion of the base chip 400 to the outside, and may also transmit signals and power from the outside to the plurality of semiconductor chips 100, 200 and 300. The base chip 400 may perform both logic and memory functions through logic devices and memory devices, but, according to an example embodiment, the base chip 400 may perform only logic functions by including only logic devices.

The substrate 401 may include, for example, a semiconductor element such as silicon or germanium (Ge), or may include a compound semiconductor such as silicon carbide (SiC), gallium arsenide (GaAs), indium arsenide (InAs), or indium phosphide (InP). The substrate 401 may have a silicon on insulator (SOI) structure. The substrate 401 may include a conductive region, for example, a well doped with impurities, or a structure doped with impurities. The substrate 401 may include various device isolation structures, such as a Shallow Trench Isolation (STI) structure.

The upper protection layer 403 may be formed on an upper surface of the substrate 401 and may protect the substrate 401. The upper protection layer 403 may be formed as an insulating layer, such as a silicon oxide film, a silicon nitride film or a silicon oxynitride film, but a material of the upper protection layer 403 is not limited to the above-described materials. For example, the upper protection layer 403 may be formed of a polymer, such as polyimide (PI) or photosensitive polyimide (PSPI). Although not illustrated in the drawing, a lower protection layer may be further formed on a lower surface of the device layer 410.

The upper pads 405 may be disposed on an upper surface of the base chip 400 (or in an upper portion of the upper protection layer 403). The upper pads 405 may include first-first upper pads 405a and first-second upper pads 405b. The first-first upper pads 405a may be disposed on the through-electrodes 430, and thus may be electrically connected to the lower pads 404 by the through-electrodes 430. The first-second upper pads 405b may be disposed on an outer side of the first-first upper pads 405a. For example, the first-second upper pads 405b may be disposed closer edges of the base chip 400 compared to the first-first second upper pads 405a. In another aspect, the first-second upper pads 405b may be disposed on an outer side of the through-electrodes 430 and might not come into contact with the through-electrodes 430, thus not forming an electrical connection path.

The first-first upper pads 405a and the first-second upper pads 405b may include the same material as each other. The upper pad 405 may include a metal. The upper pad 405 may include, for example, at least one of aluminum (Al), copper (Cu), nickel (Ni), tungsten (W), platinum (Pt), or gold (Au). The lower pad 404 may be disposed on a lower surface of the base chip 400 (or in a lower portion of the device layer 410), and may include a material similar to that of the upper pad 405. However, the materials of the upper pad 405 and the lower pad 404 are not limited to the above-described materials.

The device layer 410 may be disposed on a lower surface of the substrate 401 and may include various types of devices. For example, the device layer 410 may include FET such as planar Field Effect Transistors (FET) or FinFET, memory devices such as a flash memory, a Dynamic Random Access Memory (DRAM), a Static Random Access Memory (SRAM), an Electrically Erasable Programmable Read-Only Memory (EEPROM), a Phase-change Random Access Memory (PRAM), a Magnetoresistive Random Access Memory (MRAM), a Ferroelectric Random Access Memory (FeRAM) and a Resistive Random Access Memory (RRAM), logic devices including AND, OR and NOT, and various active devices and/or passive devices such as system Large Scale Integration (LSI), a CMOS Imaging Sensor (CIS) and a Micro-Electro-Mechanical System (MEMS). For example, the devices of the device layer 410 may be electrically connected to the lower pads 404. For example, the through-electrodes 430 may be electrically connected to the devices in the device layer 410. In an example embodiment of the present inventive concept, the device layer 410 may include conductive layers and vias, which are connected to each other and to the lower pads 404 and the through-electrodes 430.

The device layer 410 may include an interlayer insulation layer and a multilayer interconnection layer on the devices described above. For example, the interlayer insulating layer may include silicon oxide or silicon nitride. The multilayer interconnection layer may include multilayer interconnection lines and/or vertical contacts. The multilayer interconnection layer may connect devices of the device layer 410 to each other, may connect the devices to a conductive region of the substrate 401, or may connect the devices to the lower pads 404.

The through-electrodes 430 may penetrate through the substrate 401 in a vertical direction (e.g., a Z-direction) and may provide an electrical path for connecting the upper pads 405 and the lower pads 404. For example, the through-electrodes 430 may provide an electrical path for connecting the first-first upper pads 405a and the lower pads 404. The through-electrodes 430 may be electrically connected to the plurality of semiconductor chips 100, 200 and 300. The through-electrodes 430 may include a conductive plug and a barrier film surrounding the conductive plug. The conductive plug may include a metallic material, for example, tungsten (W), titanium (Ti), aluminum (Al), or copper (Cu). The conductive plug may be formed in a plating process, a PVD process, or a CVD process. For example, the barrier film may include titanium (Ti), titanium nitride (TiN), tantalum (Ta), or tantalum nitride (TaN), and may be formed in a plating process, a PVD process, or a CVD process. A side insulating film including an insulating material such as silicon oxide, silicon nitride or silicon oxynitride (for example, High Aspect Ratio Process (HARP) oxide) may be formed between a side surface of the through-electrodes 430 and the substrate 401.

Connection bumps 450 may be disposed below the base chip 400. The connection bumps 450 may be electrically connected to the plurality of semiconductor chips 100, 200 and 300 through the through-electrodes 430. The connection bumps 450 may include, for example, tin (Sn) or alloys including tin (Sn) (e.g., Sn—Ag—Cu). According to an example embodiment, the connection bumps 450 may have a form in which a metal pillar and a solder ball are combined. The connection bumps 450 may be electrically connected to an external device such as a module substrate or a system board. The base chip 400 may have a width greater than widths of each of the plurality of semiconductor chips 100, 200 and 300 in a horizontal direction (e.g., X-direction and/or Y-direction). At least some of the connection bumps 450 and at least some of the lower pads 404 may be disposed in positions that do not overlap the plurality of semiconductor chips 100, 200 and 300 in the vertical direction (Z-direction).

The first semiconductor chip 100 may be disposed on the base chip 400, and may include a first substrate 101, a first rear protection layer 103, a first front protection layer 107, first front pads 104 disposed on a first front surface of the first semiconductor chip 100, first rear pads 105 disposed on a first rear surface of the first semiconductor chip 100, a first device layer 110, a first interconnection layer 120, and first through-vias 130 electrically connecting the first front pads 104 and the first rear pads 105. The first semiconductor chip 100 may have a first front surface on which the first front pads 104 are disposed, a first rear surface on which the first rear pads 105 are disposed, and a first side surface 100S extending from an edge of the first front surface to an edge of the first rear surface.

The first substrate 101 may include, for example, a semiconductor element, such as silicon or germanium (Ge), or may include a compound semiconductor, such as silicon carbide (SiC), gallium arsenide (GaAs), indium arsenide (InAs), or indium phosphide (InP). The first substrate 101 may have a silicon on insulator (SOI) structure. The first substrate 101 may be referred to as a first semiconductor substrate.

The first substrate 101 may include a device region DR and an edge region ER surrounding the device region DR. In an example embodiment, the device region DR may be provided with a volatile memory device such as a Dynamic Random Access Memory (DRAM) or a Static Random Access Memory (SRAM), or a nonvolatile memory device such as a Phase-change Random Access Memory (PRAM), a Magnetoresistive Random Access Memory (MRAM), a Ferroelectric Random Access Memory (FeRAM), or a Resistive Random Access Memory (RRAM). In an example embodiment, the device region DR may be provided with a logic device such as a microprocessor, an analog device, or a digital signal processor.

The edge region ER may be defined as a region from the outer side of the device region DR to the first side surface 100S. The edge region ER may include a first edge region ER1 surrounding an outer side of the device region DR and a second edge region ER2 surrounding the first edge region ER1. The first edge region ER1 may include a guard ring region GR having a guard ring structure GS formed therein and a region PR in which a protrusion portion 107p of the first front protection layer 107 is formed. The second edge region ER2 may include a first region ER2a having a crack blocking structure BS formed therein and a second region ER2b surrounding the first region ER2a.

The first substrate 101 may include a conductive region 12 and an isolation region 16. The conductive region 12 may be, for example, a well doped with impurities or a structure doped with impurities. The isolation region 16 may include a device isolation structure having a shallow trench isolation (STI) structure and may include silicon oxide.

The first device layer 110 may include a lower insulating layer 111 and integrated circuit devices 11. The lower insulating layer 111 may cover the semiconductor substrate 101 and the integrated circuit devices 11. The lower insulating layer 111 may include silicon oxide, silicon nitride, silicon oxynitride, or combinations thereof. For example, the lower insulating layer 111 may include silicon oxide. The integrated circuit devices 11 may be disposed in the device region DR. The integrated circuit devices 11 may include a memory cell array including switching devices and data storage elements, and logic devices including MOSFET, a capacitor and resistance. The integrated circuit devices 11 may include, for example, FET such as planar FETs or FinFET, memory devices such as a flash memory, DRAM, SRAM, EEPROM, PRAM, MRAM, FeRAM and RRAM, logic devices such as AND, OR and NOT, and various active devices and/or passive devices such as system LSI, CIS and MEMS.

The first device layer 110 may further include a plurality of dummy connection layers 13′ and 13″ disposed in the edge region ER. The plurality of dummy connection layers 13′ and 13″ may include dummy connection layers 13′ formed in the first edge region ER1 and dummy connection layers 13″ formed in the second edge region ER2. Each of the dummy connection layers 13′ may be connected to the guard ring structure GS, and each of the dummy connection layers 13″ may be connected to the crack blocking structure BS.

The first interconnection layer 120 may be formed on the first device layer 110. The first interconnection layer 120 may include a plurality of conductive pattern layers 15a, 15b and 15c disposed at different levels in a vertical direction, an interlayer insulating layer 121a covering the conductive pattern layers 15a, 15b and 15c, and an upper insulating layer 121b. The plurality of conductive pattern layers 15a, 15b and 15c may include interconnection pattern layers 15a disposed in the device region DR, guard ring pattern layers 15b disposed in the first edge region ER1, and crack-blocking pattern layers (or ‘blocking pattern layers’) 15c disposed in the second edge region ER2. The plurality of conductive pattern layers 15a, 15b and 15c aligned in the vertical direction may form an interconnection structure CS, a guard ring structure GS, and a crack blocking structure BS described below, respectively.

The interlayer insulating layer 121a may surround the plurality of conductive pattern layers 15a, 15b and 15c and may include a low-κ dielectric material having a low dielectric constant. For example, the interlayer insulating layer 121a may include silicon oxide or an organic polymer doped with impurities. In an example embodiment, the interlayer insulating layer 121a may include SiOCH, SiCN, or combinations thereof. The interlayer insulating layer 121a may include a plurality of insulating layers sequentially stacked on the lower insulating layer 111. However, depending on the process, boundaries between the interlayer insulating layers may not be clearly distinguished. A lowermost interlayer insulating layer 121a, among the interlayer insulating layers 121a (for example, a portion covering a lowermost conductive pattern layer), may include a different material from the interlayer insulating layer 121a therebelow. For example, the lowermost interlayer insulating layer 121a may include silicon oxide.

The upper insulating layer 121b may include a plurality of insulating layers sequentially stacked on the interlayer insulating layer 121a. However, depending on the process, the boundaries between the interlayer insulating layers might not be clearly distinguished. The upper insulating layer 121b may cover lowermost pattern layers, among the plurality of conductive pattern layers 15a, 15b and 15c. The upper insulating layer 121b may include silicon nitride, silicon oxynitride, silicon carbonitride, or combinations thereof.

The plurality of conductive pattern layers 15a, 15b and 15c may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the lowermost pattern layers may include aluminum (Al), and pattern layers thereon may include copper (Cu). At least some of the plurality of conductive pattern layers 15a, 15b and 15c may include a plurality of patterns spaced apart from each other in a horizontal direction. In this specification, the ‘pattern layer’ may be understood as collectively referring to ‘patterns’ disposed on the same level. The ‘patterns’ may include an interconnection line extending in the horizontal direction and a pad connected to the interconnection line. At least some of the plurality of conductive pattern layers 15a, 15b and 15c may be vertically connected through-vias 14, 14′ and 14″.

The interconnection structure CS may include a plurality of interconnection pattern layers 15a that are vertically stacked from each other on the device region DR. The interconnection structure CS may be electrically connected to the conductive region 12 and/or at integrated circuit device 11 by means of an interconnection member 13 (e.g., a contact plug).

The guard ring structure GS may be formed to surround the device region DR. For example, the guard ring structure GS may extend in the horizontal direction to surround the interconnection structure CS in the first edge region ER1. The guard ring structure GS may include guard ring pattern layers 15b stacked in the vertical direction and/or guard via layers 14′ connecting the guard ring pattern layers 15b. The guard ring structure GS may continuously surround an outer side of the device region DR in a plane (see FIG. 3C), but the present disclosure is not limited thereto. A plurality of guard ring pattern layers 15b may be connected to each other by the guard via layers 14′. According to an example embodiment, the plurality of guard ring pattern layers 15b may be electrically insulated from each other by the interlayer insulating layer 121a. The guard ring structure GS may, for example, discontinuously surround the outer side of the device region DR in a plane. For example, the guard ring structure GS may only partially surround the device region DR or may include gaps or breaks. The guard ring structure GS may prevent cracks from propagating into the device region DR or prevent moisture from being absorbed into the device region DR.

The crack blocking structure BS may be formed to surround the first edge region ER1. For example, the crack blocking structure BS may extend in a horizontal direction in the second edge region ER2 to surround an outer edge of the first edge region ER1. The crack blocking structure BS may include a plurality of blocking pattern layers 15c stacked in the vertical direction. The crack blocking structure BS may continuously surround the guard ring structure GS on a plane (see FIG. 3C), but the present disclosure is not limited thereto. The crack blocking structure BS may, for example, discontinuously surround an outer side of the guard ring structure GS on a plane. The plurality of blocking pattern layers 15c may be connected to each other by the vias 14″. According to an example embodiment, the plurality of blocking pattern layers 15c may be electrically insulated from each other by an interlayer insulating layer 121a.

A first front protection layer 107 and an upper conductive pattern 135 may be formed on a first interconnection layer 120. The upper conductive pattern 135 may be connected to the interconnection structure CS through a conductive via. The conductive via may vertically penetrate through the upper insulating layer 121b. The upper conductive pattern 135 and the conductive via may include the same material, but the present disclosure is not limited thereto.

The first front protection layer 107 may include a horizontal portion 107h extending at least a portion in the horizontal direction and a protrusion portion 107p extending in the vertical direction from the horizontal portion 107h. The horizontal portion 107h may cover the upper conductive pattern 135 on the first interconnection layer 121b and may extend to the first side surface 100S. The protrusion portion 107p may protrude in the vertical direction from an upper surface of the horizontal portion 107h in the edge region ER, and may penetrate through the interconnection layer 120 and the device layer 110. In an example embodiment, the protrusion portion 107p may be referred to as a vertical insulating structure. An upper surface of the protrusion portion 107p may be in contact with a lower surface of the first substrate 101. In another aspect, the upper surface of the protrusion portion 107p and the lower surface of the first substrate 101 may be on the substantially same plane. A region in which the protrusion portion 107p is formed may be referred to as a vertical insulating structure region PR. The vertical insulating structure region PR may be formed between the guard ring region GR and the second edge region ER2. According to an example embodiment, the vertical insulating structure region PR may be collectively referred to as the first edge region ER1, together with the guard ring region GR.

The first front protection layer 107 may include a single-layer or multilayer insulating film. For example, the first front protection layer 107 may include silicon nitride, silicon oxynitride, silicon carbonitride, or combinations thereof. In an example embodiment, the first front protection layer 107 may include TetraEthyl OrthoSilicate (TEOS). The first front protection layer 107 may include an opening exposing at least a portion of the upper conductive pattern 135.

The upper conductive pattern 135 may include, for example, a ground pad, a power pad, an AC pad, a data pad, and a DC pad. The ground pad may be a pad for providing a reference potential for a circuit operation of a semiconductor device (e.g., a semiconductor chip 100). The power pad may be a pad for supplying power for a circuit operation. The AC pad may be a pad for supplying AC power to the semiconductor device or receiving a signal for performing an AC test. The data pad may be a pad for input/output of logic signals or data. The DC pad may be a pad for measuring a potential level of a specific position of the semiconductor device.

The first front pads 104 may be disposed on a lower surface of the first front protection layer 107 (or a lower surface of the first device layer 110). The first front pads 104 may include first-first front pads 104a formed in the device region DR and first-second front pads 104b formed in the edge region ER.

The first-first front pads 104a may include a pad portion on the first front protection layer 107 and a via portion extending vertically from the pad portion and contacting the upper conductive pattern 135. In another aspect, the first-first front pads 104a may provide an electrical connection path.

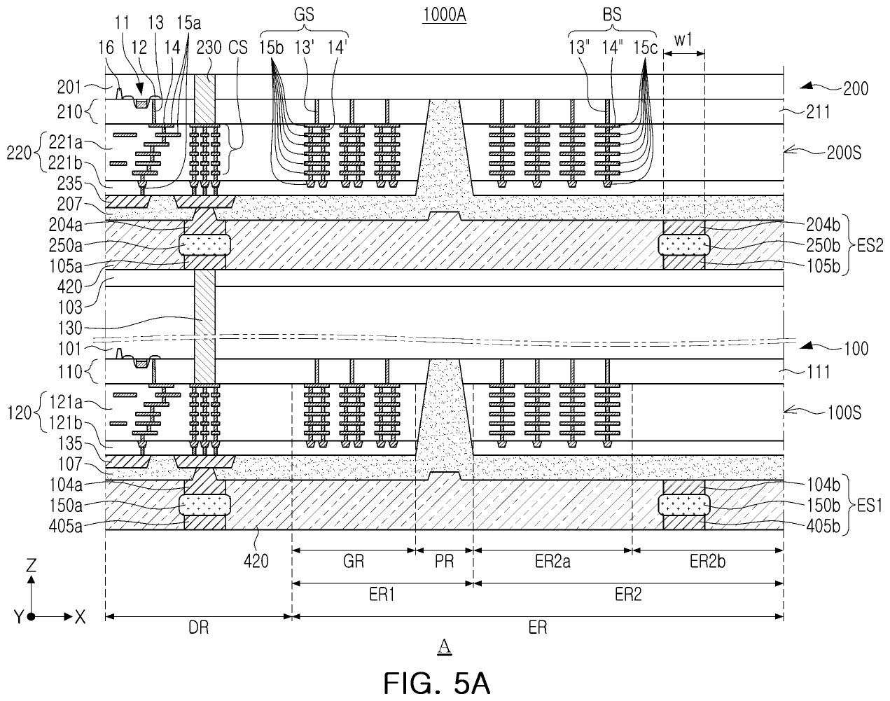

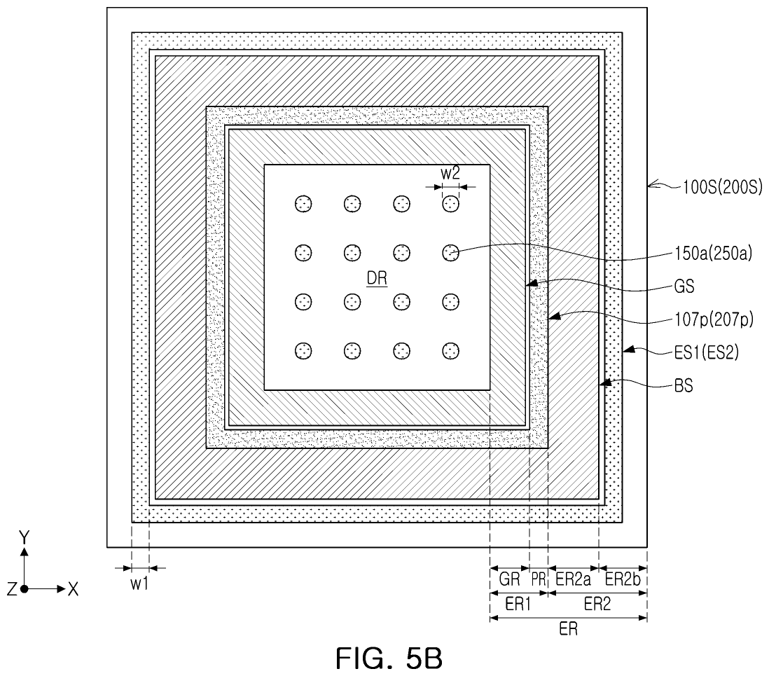

The first-second front pads 104b may be formed in the second edge region ER. The first-second front pads 104b may be formed in the first region ER2a of the second edge region ER and may be disposed to vertically overlap the crack blocking structure BS, but the present disclosure is not limited thereto. The first-second front pads 104b may be formed, for example, in the second region ER2b of the second edge region ER, and may be disposed not to overlap the crack blocking structure BS (see FIG. 5A). The first-second front pads 104b may not provide an electrical connection path, unlike the first-first front pads 104a. For example, the first-second front pads 104b may be isolated from active circuits. In an example embodiment of the present disclosure, the first-second front pads 104b may serve as dummy pads to enhance structural integrity or to maintain uniformity in the semiconductor package design. Accordingly, the first-first front pad 104a may be referred to as a first front pad, and the first-second front pad 104b may be referred to as an inactive pad.

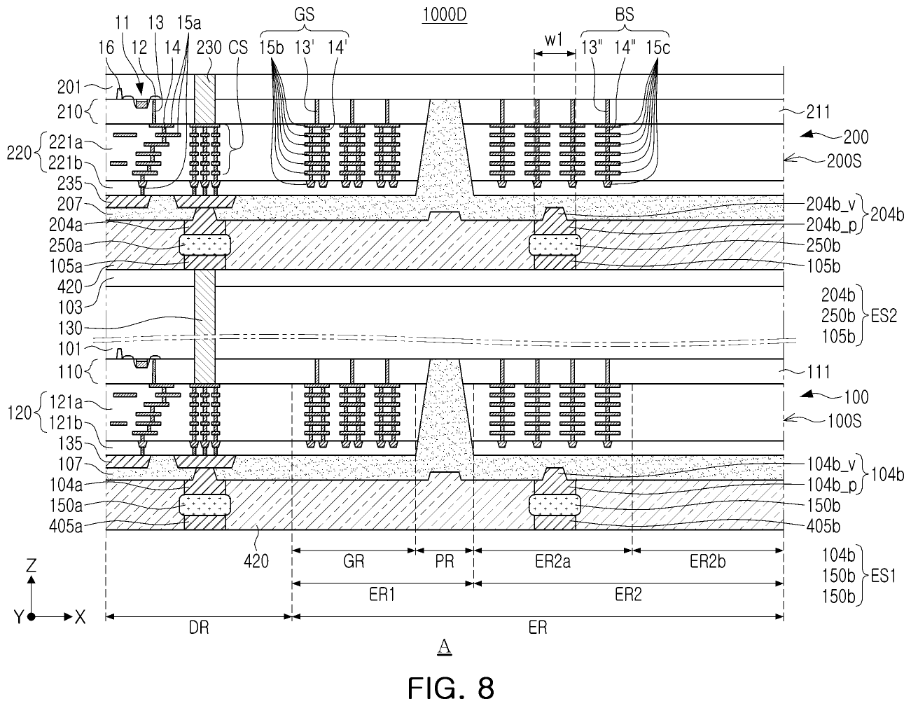

The first-second front pads 104b may include a pad portion on the first front protection layer 107, but the present disclosure is not limited thereto. The first-second front pads 104b may further include, for example, a via portion extending vertically from the pad portion and penetrating through at least a portion of the first front protection layer 107 (see FIG. 8).

The first-first front pads 104a and the first-second front pads 104b may include the same material. The first front pads 104 may include a metallic material. The first front pads 104 may include, for example, at least one of aluminum (Al), copper (Cu), nickel (Ni), tungsten (W), platinum (Pt), or gold (Au).

The first rear protection layer 103 may be formed on an upper surface of the first substrate 101 and may protect the first substrate 101. The first rear protection layer 103 may be formed of an insulating layer such as a silicon oxide film, a silicon nitride film, or a silicon oxynitride film, but the material of the first rear protection layer 103 is limited to the above-described materials. For example, the first rear protection layer 103 may be formed of a polymer such as polyimide (PI) or photosensitive polyimide (PSPI).

The first rear pads 105 may be disposed on an upper surface of the first rear protection layer 103 (or in an upper portion of the first device layer 110). The first rear pads 105 may include first-first rear pads 105a formed in the device region DR and first-second rear pads 105b formed in the edge region ER.

The first-first rear pads 105a may be formed in the device region DR and may provide an electrical connection path.

The first-second rear pads 105b may be formed in the second edge region ER2. The first-second rear pads 105b may be formed in the first region ER2a of the second edge region ER2 and may be disposed to vertically overlap the crack blocking structure BS, but the present disclosure is not limited thereto. The first-second rear pads 105b may be formed, for example, in the second region ER2b of the second edge region ER2, and may be disposed not to overlap the crack blocking structure BS (see FIG. 5A). The first-second rear pads 105b might not provide an electrical connection path, unlike the first-first rear pads 105a. For example, the first-second rear pads 105b may be isolated from active circuits. In an example embodiment of the present disclosure, the first-second rear pads 105b may serve as dummy pads to enhance structural integrity or to maintain uniformity in the semiconductor package design. Accordingly, the first-first rear pad 105a may be referred to as a first rear pad, and the first-second rear pad 105b may be referred to as an inactive pad.

The first-first rear pads 105a and the first-second rear pads 105b may include the same material. The first rear pads 105 may include a metallic material. The first rear pads 105 may include, for example, at least one of aluminum (Al), copper (Cu), nickel (Ni), tungsten (W), platinum (Pt) or gold (Au).

The first through-vias 130 may penetrate through the first substrate 101 and the first rear protection layer 103 in the vertical direction and may provide an electrical path for connecting the first-first front pads 104a and the first-first rear pads 105a in the device region DR. The first through-vias 130 may include a conductive plug and a barrier film surrounding the conductive plug. The conductive plug may include a metallic material, for example, tungsten (W), titanium (Ti), aluminum (Al), or copper (Cu). The conductive plug may be formed in a plating process, a PVD process, or a CVD process. The barrier film may include titanium (Ti), titanium nitride (TiN), tantalum (Ta), or tantalum nitride (TaN), and may be formed by a plating process, a PVD process, or a CVD process. The first through-vias 130 may be connected to an uppermost interconnection pattern layer, among the interconnection pattern layers 15a of the interconnection structure CS. According to an example embodiment, the first through-vias 130 may penetrate through the interconnection layer 120 and may thus be in direct contact with the upper conductive pattern 135.

The first connection bumps 150 may be disposed in a lower portion of the first front pads 104. The first connection bumps 150 may include first-first connection bumps 150a disposed in a lower portion of the first-first front pads 104a in the device region DR and first-second connection bumps 150b disposed in a lower portion of the first-second front pads 104b in the edge region ER.

The first-first connection bumps 150a may be disposed between the first-first front pads 104a and the first-first upper pads 405a, and may electrically connect the first-first front pads 104a and the first-first upper pads 405a.

The first-second connection bumps 150b may be disposed between the first-second front pads 104b and the first-second upper pads 405b. Unlike the first-first connection bumps 150a, the first-second connection bumps 150b might not provide an electrical connection path. According to an example embodiment, the first-first connection bump 150a may be referred to as a first connection bump, and the first-second connection bump 150b may be referred to as a bump structure.

The first-first connection bumps 150a and the first-second connection bumps 150b may include the same material. The first connection bumps 150 may include a metallic material. The first connection bumps 150 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn.

The second semiconductor chip 200 may be disposed on the first semiconductor chip 100, and may include a second substrate 201, a second rear protection layer 203, a second front protection layer 207, second front pads 204 disposed on a second front surface of the second semiconductor chip 200, second rear pads 205 disposed on a second rear surface of the second semiconductor chip 200, a second device layer 210, a second interconnection layer 220, and second through-vias 230 electrically connecting the second front pads 204 and the second rear pads 205. The second semiconductor chip 200 may have a second front surface on which the second front pads 204 are disposed, a second rear surface on which the second rear pads 205 are disposed, and a second side surface 200S extending from an edge of the second front surface to an edge of the second rear surface.

Since the second substrate 201 has characteristics identical to or similar to those of the first substrate 101, redundant description thereof may be omitted. The second substrate 201 may be referred to as a second semiconductor substrate.

The second substrate 201 may include a device region DR and an edge region ER surrounding the device region DR. The device region DR and the edge region ER of the second substrate 201 may have characteristics substantially identical to or similar to those of the device region DR and the edge region ER of the first substrate 101. The edge region ER may be defined as a region from an outer side of the device region DR to the second side 200S. The edge region ER may include a first edge region ER1 surrounding the outer side of the device region DR and a second edge region ER2 surrounding the first edge region ER1. The first edge region ER1 may include a guard ring region GR in which a guard ring structure GS is formed and a region PR in which a protrusion portion 207p of the second front protection layer 207 is formed. The second edge region ER2 may include a first region ER2a in which a crack blocking structure BS is formed and a second region ER2b surrounding the first region ER2a.

Since the second device layer 210 has characteristics identical to or similar to those of the first device layer 110, redundant descriptions may be omitted. The second device layer 210 may include a lower insulating layer 211 and integrated circuit devices 11. The lower insulating layer 211 of the second device layer 210 may have characteristics identical to or similar to those of the lower insulating layer 111 of the first device layer 110.

Since the second interconnection layer 220 has characteristics identical to or similar to those of the first interconnection layer 120, redundant descriptions may be omitted. The second interconnection layer 220 may include an interlayer insulating layer 221a and an upper insulating layer 221b. The interlayer insulating layer 221a and the upper insulating layer 221b of the second interconnection layer 220 may have characteristics substantially identical to or similar to those of the interlayer insulating layer 121a and the upper insulating layer 121b of the first interconnection layer 120.

A second front protection layer 207 and an upper conductive pattern layer 235 may be formed on the second interconnection layer 220. Each of the second front protection layer 207 and the upper conductive pattern layer 235 may have characteristics substantially identical to or similar to those of each of the first front protection layer 107 and the upper conductive pattern 135.

The second front pads 204 may be disposed on a lower surface of the second front protection layer 207 (or in a lower portion of the second device layer 210). The second front pads 204 may include second-first front pads 204a formed in the device region DR and second-second front pads 204b formed in the edge region ER.

The second-first front pads 204a may include a pad portion on the second front protection layer 207 and a via portion extending vertically from the pad portion and contacting the upper conductive pattern layer 235. In another aspect, the second-first front pads 204a may provide an electrical connection path.

The second-second front pads 204b may be formed in the second edge region ER2. The second-second front pads 204b may be formed in the first region ER2a of the second edge region ER2 and may be disposed to vertically overlap the crack blocking structure BS, but the present disclosure is not limited thereto. The second-second front pads 204b may be formed, for example, in the second region ER2b of the second edge region ER2 and may be disposed not to overlap the crack blocking structure BS (see FIG. 5A). For example, the second-second front pads 204b may be isolated from active circuits. In an example embodiment of the present disclosure, the second-second front pads 204b may serve as dummy pads to enhance structural integrity or to maintain uniformity in the semiconductor package design. Unlike the second-first front pads 204a, the second-second front pads 204b might not provide an electrical connection path. Accordingly, the second-first front pad 204a may be referred to as a second front pad, and the second-second front pad 204b may be referred to as an inactive pad.

The second-second front pads 204b may include a pad portion on the first front protection layer 207, but the present disclosure is not limited thereto. The second-second front pads 204b may further include, for example, a via portion extending vertically from the pad portion and penetrating through at least a portion of the second front protection layer 207 (see FIG. 8).

The second-first front pads 204a and the second-second front pads 204b may include the same material. The second front pads 204 may include a metallic material. The second front pads 204 may include, for example, at least one of aluminum (Al), copper (Cu), nickel (Ni), tungsten (W), platinum (Pt), or gold (Au).

The second rear protection layer 203 may be formed on an upper surface of the second substrate 201 and may protect the second substrate 201. The second rear protection layer 203 may have characteristics substantially identical to or similar to those of the first rear protection layer 103.

The second rear pads 205 may be disposed on an upper surface of the second rear protection layer 203 (or in an upper portion of the second device layer 210). The second rear pads 205 may include second-first rear pads 205a formed in the device region DR and second-second rear pads 205b formed in the edge region ER (see FIG. 1).

The second-first rear pads 205a may be be formed in the device region DR and may provide an electrical connection path.

The second-second rear pads 205b may be formed in the second edge region ER2. The second-second rear pads 205b may be formed in the first region ER2a of the second edge region ER and may be disposed to vertically overlap the crack blocking structure BS, but the present disclosure is not limited thereto. The second-second rear pads 205b may be formed, for example, in the second region ER2b of the second edge region ER2 and may be disposed not to overlap the crack blocking structure BS (see FIG. 5A). Unlike the second-first rear pads 205a, the second-second rear pads 205b might not provide an electrical connection path. For example, the second-second rear pads 205b may be isolated from active circuits. In an example embodiment of the present disclosure, the second-second rear pads 205b may serve as dummy pads to enhance structural integrity or to maintain uniformity in the semiconductor package design. Accordingly, the second-first rear pad 205a may be referred to as a second front pad, and the second-second rear pad 205b may be referred to as an inactive pad.

The second-first rear pads 205a and the second-second rear pads 205b may include the same material. The second rear pads 205 may include a metallic material. The second rear pads 205 may include, for example, at least one of aluminum (Al), copper (Cu), nickel (Ni), tungsten (W), platinum (Pt) or gold (Au).

The second through-vias 230 may vertically penetrate through the second substrate 201 and the second rear protection layer 203, and may provide an electrical path for connecting the second-first front pads 204a and the second-first rear pads 205a in the device region DR. The second through-vias 230 may include a conductive plug and a barrier film surrounding the conductive plug. The conductive plug may include a metallic material, for example, tungsten (W), titanium (Ti), aluminum (Al) or copper (Cu). The conductive plug may be formed in a plating process, a PVD process or a CVD process. The barrier film may include titanium (Ti), titanium nitride (TiN), tantalum (Ta) or tantalum nitride (TaN), and may be formed in the plating process, the PVD process or the CVD process. The second through-vias 230 may be connected to an uppermost interconnection pattern layer, among the interconnection pattern layers 15a of the interconnection structure CS. According to an example embodiment, the second through-vias 230 may penetrate through the interconnection layer 220 and may thus be in direct contact with the upper conductive pattern layer 235.

The second connection bumps 250 may be disposed in a lower portion of the second front pads 204. The second connection bumps 250 may include second-first connection bumps 250a disposed in a lower portion of the second-first front pads 204a in the device region DR and second-second connection bumps 250b disposed in a lower portion of the second-second front pads 204b in the edge region ER.

The second-first connection bumps 250a may be disposed between the second-first front pads 204a and the first-first rear pads 105a, and may electrically connect the second-first front pads 204a and the first-first rear pads 105a.

The second-second connection bumps 250b may be disposed between the second-second front pads 204b and the first-second rear pads 105b. The second-second connection bumps 250b may not provide an electrical connection path, unlike the second-first connection bumps 250a. According to an example embodiment, the second-first connection bumps 250a may be referred to as second connection bumps, and the second-second connection bumps 250b may be referred to as bump structures.

The second-first connection bumps 250a and the second-second connection bumps 250b may include the same material. The second connection bumps 250 may include a metallic material. The second connection bumps 250 may include, for example, tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn.

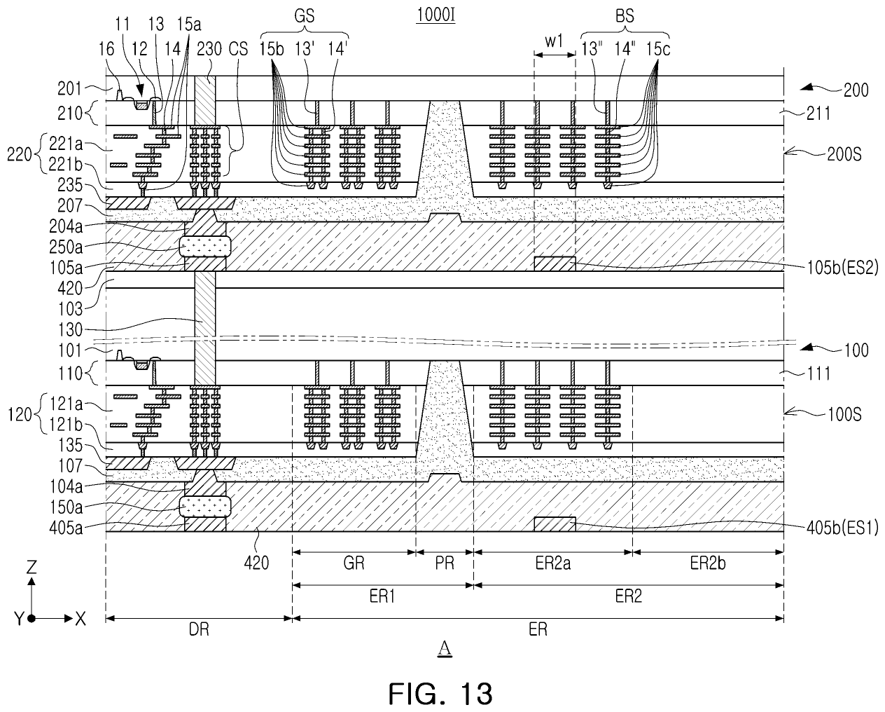

According to an example embodiment, the number of the plurality of second semiconductor chips 200 may be one or three or more. The number of the plurality of second semiconductor chips 200 may be, for example, 10 (see FIG. 13).

The third semiconductor chip 300 may be disposed on the second semiconductor chip 200, and may include a third substrate 301, a third front protection layer (not illustrated), third front pads 304 disposed on a third front surface, a third device layer 310, and a third interconnection layer (not illustrated). The third semiconductor chip 300 may have the third front surface on which the third front pads 304 are disposed, a third rear surface exposed from the encapsulant 425, and a third side surface 300S extending from an edge of the third front surface to an edge of the third rear surface.

Since the third substrate 301 and the third device layer 310 have characteristics identical to or similar to those of the substrate 401 and the device layer 410, which are the corresponding components of the base chip 400 described above, redundant descriptions thereof may be omitted. Since the third front protection layer (not illustrated) has characteristics identical to or similar to those of the first front protection layer 107 and/or the second front protection layer 207, redundant descriptions thereof may be omitted.

The third front pads 304 may be disposed in a lower portion of the third device layer 310. The third front pads 304 may include third-first front pads 304a formed in the device region DR and third-second front pads 304b formed in the edge region ER.

The third-first front pads 304a may be formed in the device region DR and may provide an electrical connection path. The third-second front pads 304b may be formed in the edge region ER and might not provide an electrical connection path. For example, the third-second rear pads 304b may be isolated from active circuits. In an example embodiment of the present disclosure, the third-second rear pads 305b may serve as dummy pads to enhance structural integrity or to maintain uniformity in the semiconductor package design. The third-first front pads 304a may be referred to as third front pads, and the third-second front pads 304b may be referred to as inactive pads.

The third-first front pads 304a and the third-second front pads 304b may include the same material. The third front pads 304 may include a metallic material. The third front pads 304 may include, for example, at least one of aluminum (Al), copper (Cu), nickel (Ni), tungsten (W), platinum (Pt) or gold (Au).

The third connection bumps 350 may be disposed on a lower portion of the third front pads 304. The third connection bumps 350 may include third-first connection bumps 350a disposed on a lower portion of the third-first front pads 304a in the device region DR and third-second connection bumps 350b disposed in lower portions of the third-second front pads 304b in the edge region ER.

The third-first connection bumps 350a may be disposed between the third-first front pads 304a and the second-first rear pads 205a, and may electrically connect the third-first front pads 304a and the second-first rear pads 205a.

The third-second connection bumps 350b may be disposed between the third-second front pads 304b and the second-second rear pads 205b. Unlike the third-first connection bumps 350a, the third-second connection bumps 350b might not provide an electrical connection path. According to an example embodiment, the third-first connection bump 350a may be referred to as a third connection bump, and the third-second connection bump 350b may be referred to as a bump structure.

The third-first connection bumps 350a and the third-second connection bumps 350b may include the same material. The third connection bumps 350 may include a metallic material. The third connection bumps 350 may include, for example, tin (Sn), indium (In), bismuth (Bi), antimony (Sb), copper (Cu), silver (Ag), zinc (Zn), lead (Pb) and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn.

The adhesive layers 420 may surround the connection bumps 150, 250 and 350 disposed between the plurality of semiconductor chips 100, 200 and 300, and may fix the plurality of semiconductor chips 100, 200 and 300 onto the base chip 400. The adhesive layers 420 may be a Non Conductive Film (NCF), but the present disclosure is not limited thereto, and may include, for example, all types of polymer films capable of performing a thermocompression process. The adhesive layer disposed on a front surface of the first semiconductor chip 100 may be referred to as a first adhesive layer, and the adhesive layer disposed on a front surface of the second semiconductor chip 200 may be referred to as a second adhesive layer.

The adhesive layer 420 may include a horizontal portion 420h in which at least a portion thereof extends in the horizontal direction and a protrusion portion 420p extending in the vertical direction from the horizontal portion 420h. The protrusion portion 420p may protrude in the vertical direction from an upper surface of the horizontal portion 420h, in the vertical insulating structure region PR, and may penetrate through at least portions of lower regions of the horizontal portion 107h and 207h of the front protection layers 107 and 207. The protrusion portion 420p of the adhesive layer 420 may be formed in lower portions of the protrusion portions 107p and 207p of the front protection layers 107 and 207.

A horizontal portion 420_h may cover the upper conductive pattern 135 on the first interconnection layer 121b and may extend to the first side surface 100S. The protrusion portion 107p may protrude in the vertical direction from the upper surface of the horizontal portion 107h, in the edge region ER, and may penetrate through the interconnection layer 120 and the device layer 110. An upper surface of the protrusion portion 107p may be in contact with the lower surface of the first substrate 101. In another aspect, the upper surface of the protrusion portion 107p and the lower surface of the first substrate 101 may be on substantially the same plane. A region in which the protrusion portion 107p is formed may be referred to as a vertical insulating structure region PR. The vertical insulating structure region PR may be formed between the guard ring region GR and the second edge region ER2. According to an example embodiment, the vertical insulating structure region PR may be collectively referred to as the first edge region ER1 together with the guard ring region GR.

The encapsulant 425 may encapsulate the plurality of semiconductor chips 100, 200 and 300 on the base chip 400. The encapsulant 425 may be formed to expose a rear surface of the third semiconductor chip 300. According to an example embodiment, the encapsulant 425 may be formed to cover the rear surface of the third semiconductor chip 300. The encapsulant 425 may be formed of, for example, an insulating material such as an Epoxy Mold Compound (EMC), but the material of the encapsulant 425 is not particularly limited. The encapsulant 425 may surround side surfaces of the plurality of semiconductor chips 100, 200 and 300. The encapsulant 425 may directly contact the side surfaces 100S, 200S and 300S of each of the plurality of semiconductor chips 100, 200 and 300 and side surfaces of the adhesive layers 420. According to an example embodiment, a heat dissipation structure may be disposed in an upper portion of the encapsulant 425. The heat dissipation structure may control warpage of the semiconductor package 1000 and may dissipate heat generated by the plurality of semiconductor chips 100, 200 and 300 to an external environment.

In an example embodiment, the first-second upper pad 405b, the first-second front pad 104b, and the first-second connection bump 150b between the first-second upper pad 405b and the first-second front pad 104b may be referred to as a first edge structure ES1.

In an example embodiment, the first-second rear pad 105b, the second-second front pad 204b, and the second-second connection bump 250b between the first-second rear pad 105b and the second-second front pad 204b may be referred to as a second edge structure ES2.

A maximum width W1 of each of the first and second edge structures ES1 and ES2 in the horizontal direction may be defined as a maximum width of each of the first-second and second-second connection bumps 150b and 250b in the horizontal direction. The maximum width W1 may be substantially the same as a maximum width W2 of each of the first-first and second-first connection bumps 150a and 250a in the horizontal direction. The maximum width W1 may be approximately 5 μm or more. In an example embodiment, the maximum width W1 may be in a range of approximately 5 μm or more and approximately 15 μm or less. In an example embodiment, the maximum width W1 may be in a range of approximately 5 μm or more and approximately 15 μm or less. The term “approximate” or its equivalent term such as “about” may mean that the parameter being describe has the exact value or around the value with some variation (e.g., ±2%, ±5%, or ±10% of the value) due to a process/measurement error or tolerance, recognized by one of ordinary skill in the art.

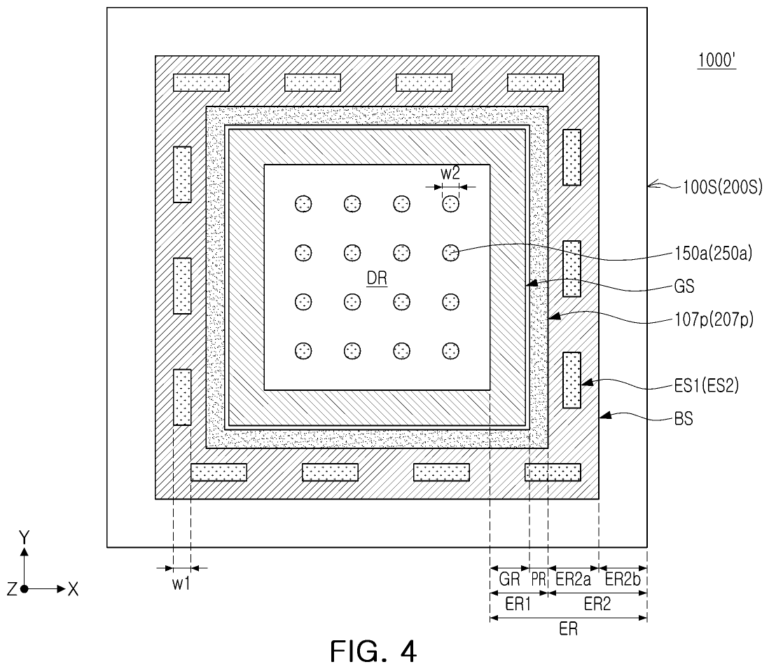

Referring to FIG. 3C, the first edge structure ES1 may continuously surround the first-first connection bumps 150a, and the second edge structure ES2 may continuously surround the second-first connection bumps 250a, but the present disclosure is not limited thereto. For example, at least one of the first and second edge structures ES1 and ES2 may discontinuously surround the connection bumps 150a and 250a disposed in the device region DR (see FIG. 4).

The first edge structure ES1 may include a material having a thermal expansion coefficient that is lower than that of the first adhesive layer. The first adhesive layer may include, for example, a non-conductive material, and at least a portion of the first edge structure ES1 may include a conductive material such as a metal. According to an example embodiment of the present disclosure, the first edge structure ES1 may be formed so as to overlap the edge region ER between the base chip 400 and the first semiconductor chip 100, thereby reducing the volume and/or mass of the first adhesive layer. Accordingly, cracks or damage that may propagate to the base chip 400 and/or the first semiconductor chip 100 along the first adhesive layer may be minimized or prevented.

Similar to the above, the second edge structure ES2 may include a material having a thermal expansion coefficient that is lower than that of the second adhesive layer. The second adhesive layer may include, for example, a non-conductive material, and at least a portion of the second edge structure ES2 may include a conductive material such as a metal. According to an example embodiment of the present disclosure, the second edge structure ES2 may be formed to overlap the edge region ER between the first semiconductor chip 100 and the second semiconductor chip 200 and between the second semiconductor chips 200 adjacent to each other, thereby reducing the volume and/or mass of the second adhesive layer. Accordingly, cracks or damage that may propagate to the first semiconductor chip 100 and/or the second semiconductor chip 200 along the second adhesive layer may be minimized or prevented.

FIG. 4 is a plan view illustrating a semiconductor package according to an example embodiment.

Referring to FIG. 4, a semiconductor package 1000′ may be the same as or similar to that described with reference to FIGS. 1 to 3C, except that the semiconductor package 1000′ may include first and/or second edge structures ES1 and ES2 discontinuously surrounding the connection bumps 150a and 250a disposed to overlap the device region DR.

At least one of the first and second edge structures ES1 and ES2 may discontinuously surround the corresponding first-first and second-first connection bumps 150a and 250a. For example, at least one of the first and second edge structures ES1 and ES2 may have a plurality of components spaced apart from each other in the horizontal direction (e.g., X-direction and/or Y-direction).

FIG. 5A is a partially enlarged view of a semiconductor package according to an example embodiment. FIG. 5B is a plan view illustrating the semiconductor package of FIG. 5A

Referring to FIGS. 5A and 5B, a semiconductor package 1000A may be the same as or similar to that described with reference to FIGS. 1 to 4, except that the semiconductor package 1000A may include first and/or second edge structures ES1 and ES2 disposed to overlap the second region ER2b of the second edge region ER2.

At least one of the first and second edge structures ES1 and ES2 may be disposed to vertically overlap the second region ER2b. In another aspect, at least one of the first and second edge structures ES1 and ES2 may not vertically overlap the crack blocking structure BS of the first region ER2a. For example, at least one of the first edge structures ES1 or the second edge structure ES2 may be disposed outside of the crack blocking structure BS that is located in the first region ER2a of the second edge region ER2.

Additionally, at least one of the first and second edge structures ES1 and ES2 may be formed to vertically overlap the first region ER2a and the second region ER2b (not illustrated). For example, at least a portion of the first edge structure ES1 may be formed to vertically overlap the first region ER2a, and the remaining portion of the first edge structure ES1 may be formed to vertically overlap the second region ER2b.

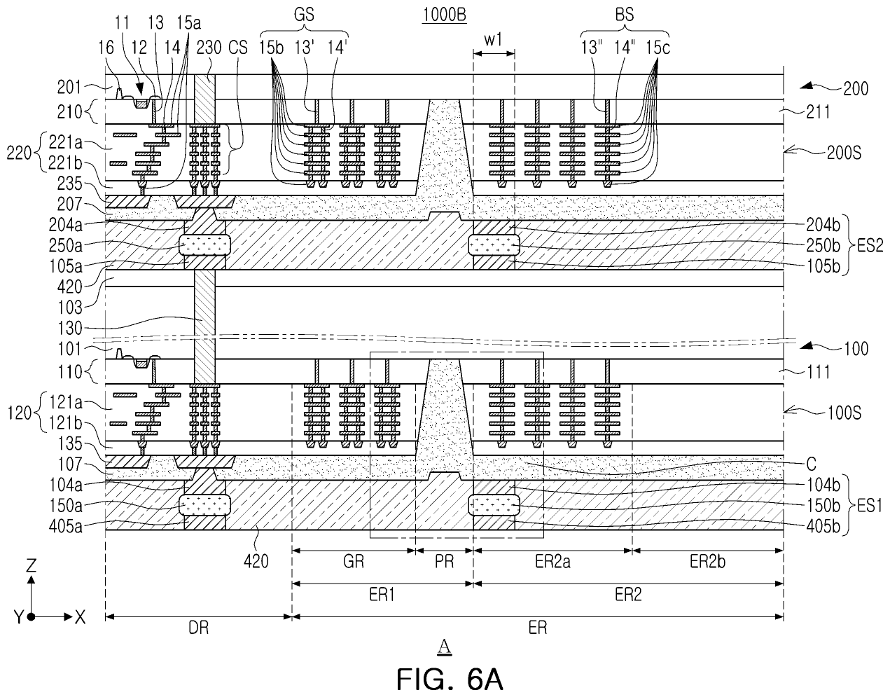

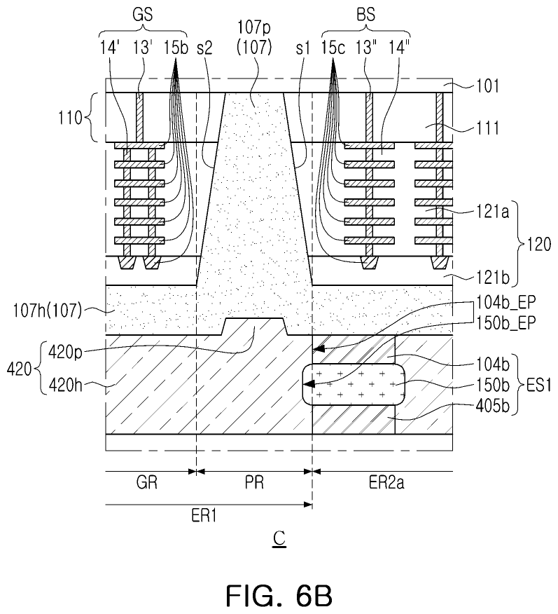

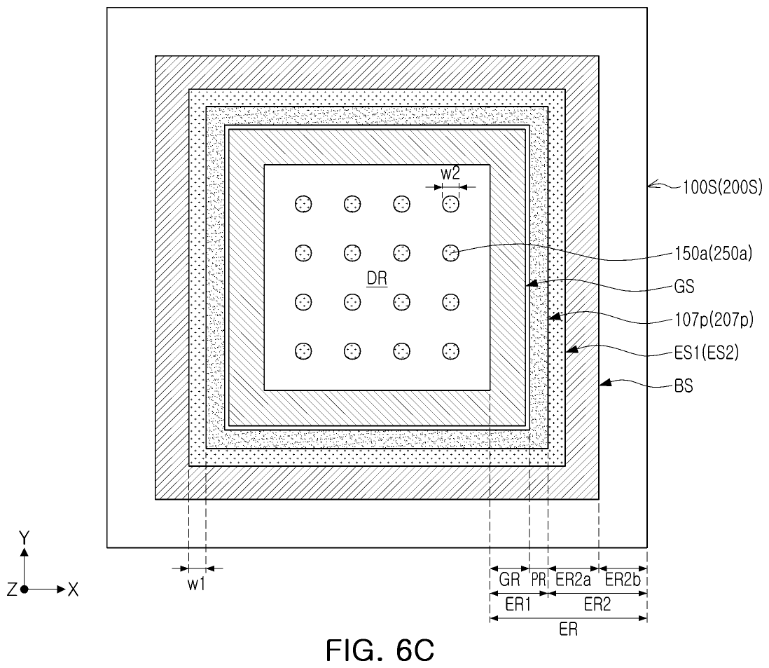

FIG. 6A is a partially enlarged view of a semiconductor package according to an example embodiment. FIG. 6B is a partially enlarged view illustrating region ‘C’ of FIG. 6A. FIG. 6C may be a plan view illustrating some of components of the semiconductor package of FIG. 6A to explain a arrangement relationship of the first and second edge structures ES1 and ES2.

Referring to FIGS. 6A to 6C, a semiconductor package 1000B may be the same as or similar to that described with reference to FIGS. 1 to 5B, except that an end (e.g., 104b_EP) may include first and/or second edge structures ES1 and ES2 in boundaries between the first edge region ER1 and the second edge region ER2,

A protrusion portion 103p may have a first side s1 facing a side surface of the first semiconductor chip 100S and a second side s2 opposite to the first side s1. The first side s1 may be a portion close to the crack blocking structure BS, and the second side s2 may be a portion close to the guard ring structure GS. For example, the first side s1 may face the crack blocking structure BS, and the second side s2 may face the guard ring structure GS.

An end of at least a portion of the first edge structure ES1 may be aligned with a portion in which the first side s1 of the protrusion portion 103p is connected to a horizontal portion 103h. Here, the end of the at least portion of the first edge structure ES1 may be defined as an end 104b_EP of the first-second front pad 104b. For example, the end 104b_EP of the first-second front pad 104b may be aligned with a point of contact between the first side s1 of the protrusion portion 107p and the upper surface of the horizontal portion 107h.

An end 150b_EP of the first-second connection bump 150b of the first edge structure ES1 might not be aligned with a portion in which the first side s1 of the protrusion portion 107p is connected to the horizontal portion 107h. In another aspect, the end 150b_EP of the first-second connection bump 150b may vertically overlap the protrusion portion 107p. For example, the end 150b_EP of the first-second connection bump 150b is not aligned with the end 104b_EP of the first-second front pad 104b.

The second edge structure ES2 may also have characteristics substantially identical to or similar to the first edge structure ES1, similarly to those described above.

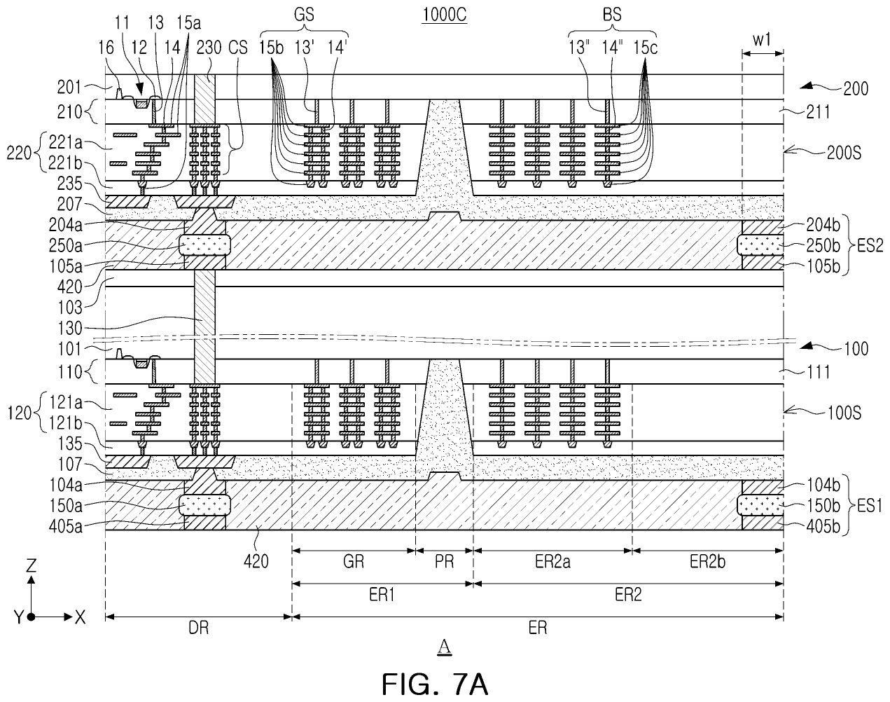

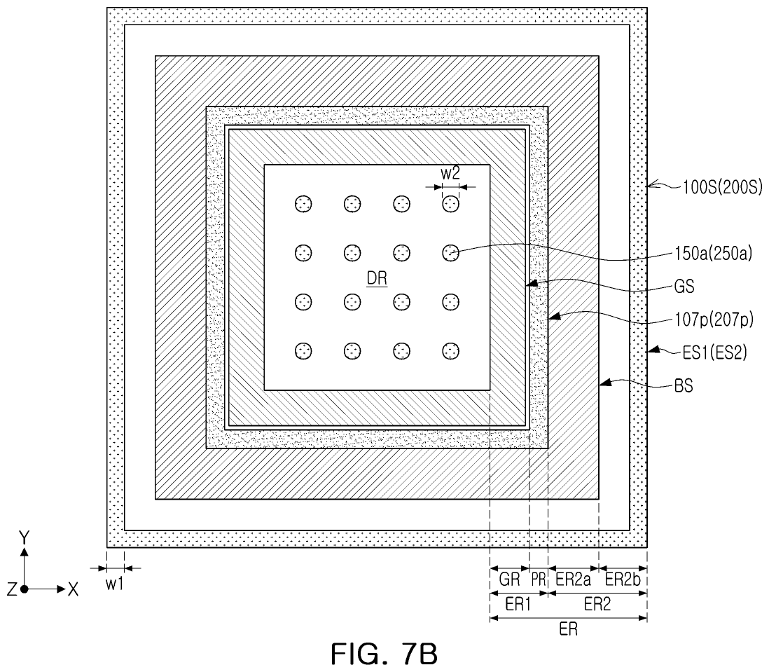

FIG. 7A is a partially enlarged view of a semiconductor package according to an example embodiment.

FIG. 7B may be a plan view illustrating some of components of the semiconductor package of FIG. 7A, in order to explain an arrangement relationship of the first and second edge structures ES1 and ES2.

Referring to FIGS. 7A and 7B, a semiconductor package 1000C may be the same as or similar to that described with reference to FIGS. 1 to 6C, except that an end thereof may include first and/or second edge structures ES1 and ES2 aligned with the side surfaces 100S and 200S of the semiconductor chips 100 and 200.

At least one of the first and second edge structures ES1 and ES2 may have an end aligned with the side surfaces 100S and 200S of the corresponding semiconductor chips 100 and 200.

A side surface of the first-second connection bump 150b may be aligned with a side surface of the first-second top pad 405b and a side surface of the first-second front pad 104b. The side surface of the first-second connection bump 150b may have a flat surface.

A side surface of the second-second connection bump 250b may be aligned with a side surface of the first-second rear pad 105b and a side surface of the second-second front side pad 204b. The side surface of the second-second connection bump 250b may have a flat surface.

FIG. 8 is a partially enlarged view of a semiconductor package according to an example embodiment.

Referring to FIG. 8, a semiconductor package 1000D may be the same as or similar to that described with reference to FIGS. 1 to 7B, except that the semiconductor package 1000D may include first and/or second edge structures ES1 and ES2 including front pads 104b and 204b further including via portions 104b_v and 204b_v.

The first-second front pad 104b of the first edge structure ES1 may further include the via portion 104_v extending in the vertical direction from an upper surface of the pad portion 104_p and penetrating through at least a portion of the first front protection layer 107. An upper surface of the via portion 104_v of the first-second front pad 104b and an upper surface of the first-first front pad 104a may be on substantially the same plane. For example, an upper surface of the via portion 104_v of the first-second front pad 104b and an upper surface of the via portion of the first-first front pad 104a may be on substantially the same plane. The via portion 104_v may include substantially the same material as the pad portion 104_p.

The second-second front pad 204b of the second edge structure ES2 may also have characteristics substantially identical to or similar to the first-second front pad 104b of the first edge structure ES1, similar to the above.

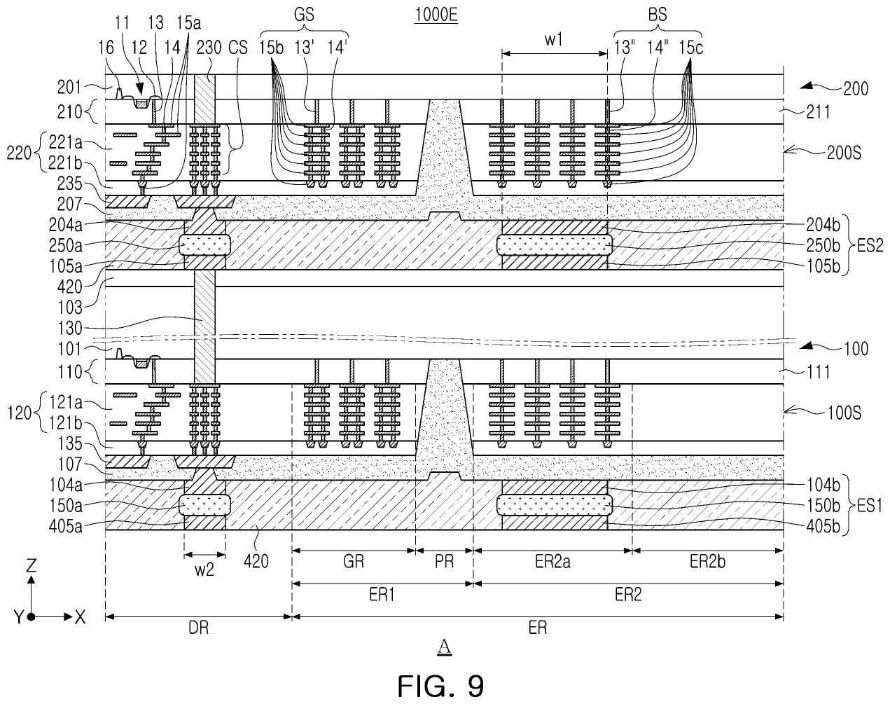

FIG. 9 is a partially enlarged view of a semiconductor package according to an example embodiment.

Referring to FIG. 9, a semiconductor package 1000E may be the same as or similar to that described with reference to FIGS. 1 to 8, except that the semiconductor package 1000E includes a first edge structure ES1 having a horizontal width W1 greater than a horizontal width W2 of the first-first front pad 104a, and/or a second edge structure ES2 having a horizontal width W1 greater than a horizontal width W2 of the second-first front pad 204a.

A maximum width W1 of the first-second front pad 104b of the first edge structure ES1 in the horizontal direction may be greater than a maximum width W2 of the first-first front pad 104a in the horizontal direction. Here, the maximum width W1 may be approximately 5 μm or more. In an example embodiment, the maximum width W1 may be in a range of approximately 5 μm or more and approximately 100 μm or less. In an example embodiment, the maximum width W1 may be in a range of approximately 5 μm or more and approximately 50 μm or less.

The maximum width W1 of the second edge structure ES2 may also have characteristics substantially identical to or similar to the maximum width W1 of the first edge structure ES1, similar to the above.

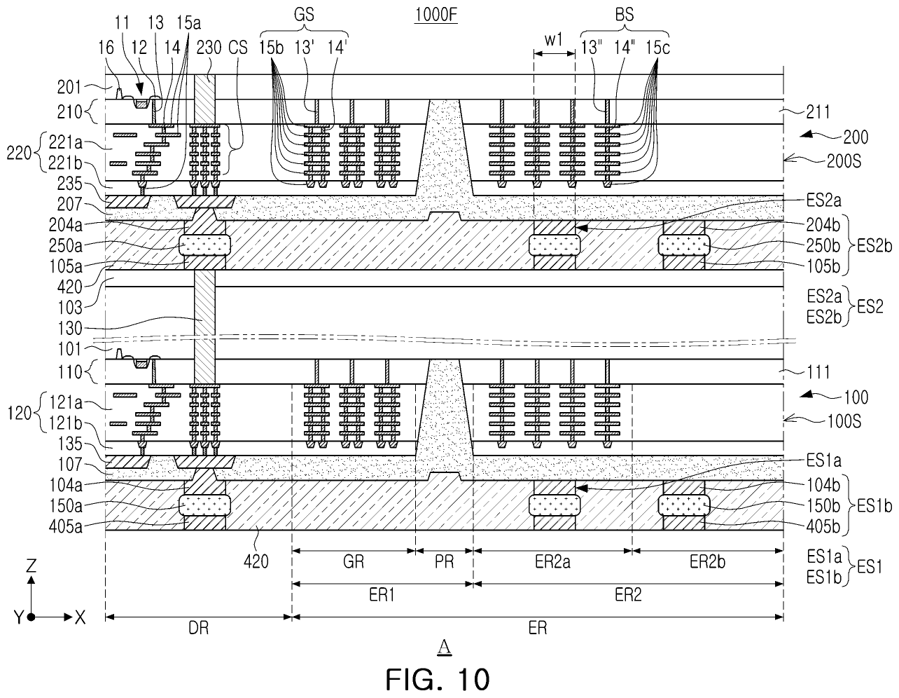

FIG. 10 is a partially enlarged view of a semiconductor package according to an example embodiment.

Referring to FIG. 10, a semiconductor package 1000F may be the same as or similar to those described with reference to FIGS. 1 to 9, except that the semiconductor package 1000F includes first and/or second edge structures ES1 and ES2 including a plurality of structures surrounding an outer side of the device region DR with a plurality of layers.

The first edge structure ES1 may include a first structure ES1a surrounding the outer side of the device region DR and a second structure ES1b surrounding the first structure ES1a. The first structure ES1a may surround the outer side of the device region DR continuously or discontinuously (see FIGS. 3C and 4). The second structure ES1b may surround the outer side of the first structure ES1a continuously or discontinuously (see FIGS. 3C and 4). The first edge structure ES1 may further include a third structure (not illustrated) surrounding the second structure ES1b continuously or discontinuously.

The first structure ES1a may be disposed in the first region ER2a, and the second structure ES1b may be disposed in the second region ER2b, but the present disclosure is not limited thereto. For example, the first and second structures ES1a and ES1b may be disposed in the first region ER2a, the first and second structures ES1a and ES1b may be disposed in the second region ER2b, or at least one of the first and second structures ES1a and ES1b may be disposed to overlap both the first and second regions ER2a and ER2b.

The second edge structure ES2 may also have characteristics substantially identical to or similar to the first edge structure ES1, similar to the above.

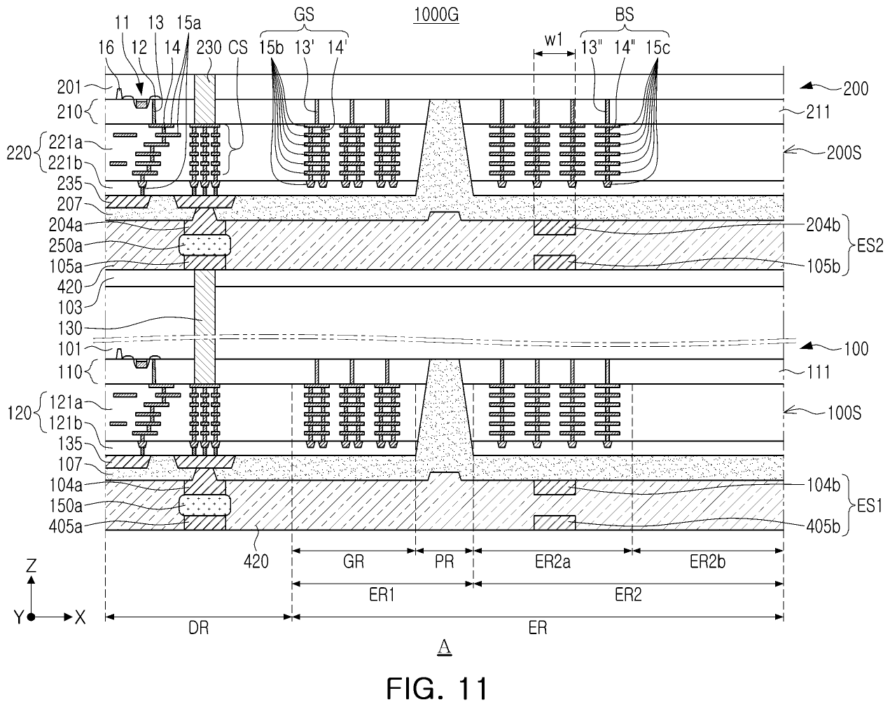

FIG. 11 is a partially enlarged view of a semiconductor package according to an example embodiment.

Referring to FIG. 11, a semiconductor package 1000G may be the same as or similar to that described with reference to FIGS. 1 to 10, except that the semiconductor package 1000G includes first and/or second edge structures ES1 and ES2 including front pads 104b and 204b and upper and rear pads 405b and 105b.

The first edge structure ES1 may include the first-second front pad 104b and the first-second top pad 405b. In another aspect, the first edge structure ES1 may not include the connection bump (‘150b’ in FIG. 3).

The second edge structure ES2 may include the second-second front pad 204b and the first-second rear pad 105b. In another aspect, the second edge structure ES2 might not include the connection bump (‘250b’ in FIG. 3).

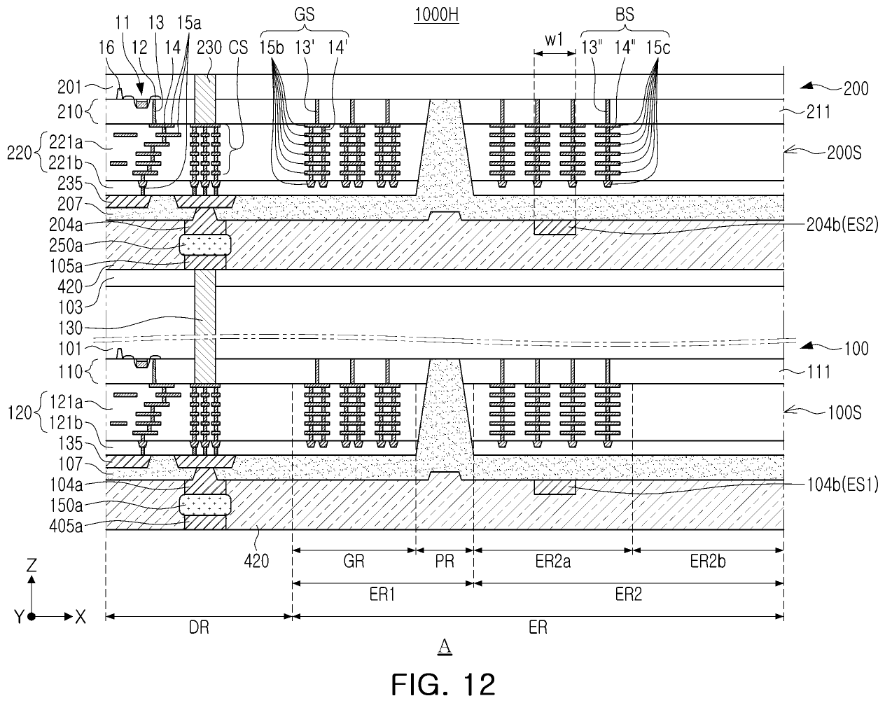

FIG. 12 is a partially enlarged view of a semiconductor package according to an example embodiment.

Referring to FIG. 12, a semiconductor package 1000H may be the same as or similar to that described with reference to FIGS. 1 to 11, except that the semiconductor package 1000H includes first and/or second edge structures ES1 and ES2 including the front pads 104b and 204b.

The first edge structure ES1 may include the first-second front pads 104b. In another aspect, the first edge structure ES1 might not include the upper pad (‘405b’ in FIG. 3A) and the connection bump (‘150b’ in FIG. 3). In another aspect, the first edge structure ES1 may be disposed to contact the first semiconductor chip 100.

The second edge structure ES2 may also have characteristics substantially identical to or similar to the first edge structure ES1, similar to the above.

FIG. 13 is a partially enlarged view of a semiconductor package according to an example embodiment.

Referring to FIG. 13, a semiconductor package 1000I may be the same as or similar to those described with reference to FIGS. 1 to 12, except that the semiconductor package 1000I includes first and/or second edge structures ES1 and ES2 including the first-second upper pad 405b or the first-second rear pad 105b.

The first edge structure ES1 may include the upper pad 405b. In another aspect, the first edge structure ES1 might not include the front pad (‘104b’ of FIG. 3A) and the connection bump (‘150b’ of FIG. 3). In another aspect, the first edge structure ES1 may be disposed to contact the base chip 400.

The second edge structure ES2 may include the first-second rear pad 105b. In another aspect, the second edge structure ES2 might not include the front pad (‘204b’ of FIG. 3A) and the connection bump (‘250b’ of FIG. 3). In another aspect, the second edge structure ES2 may be disposed to contact the first semiconductor chip 100.

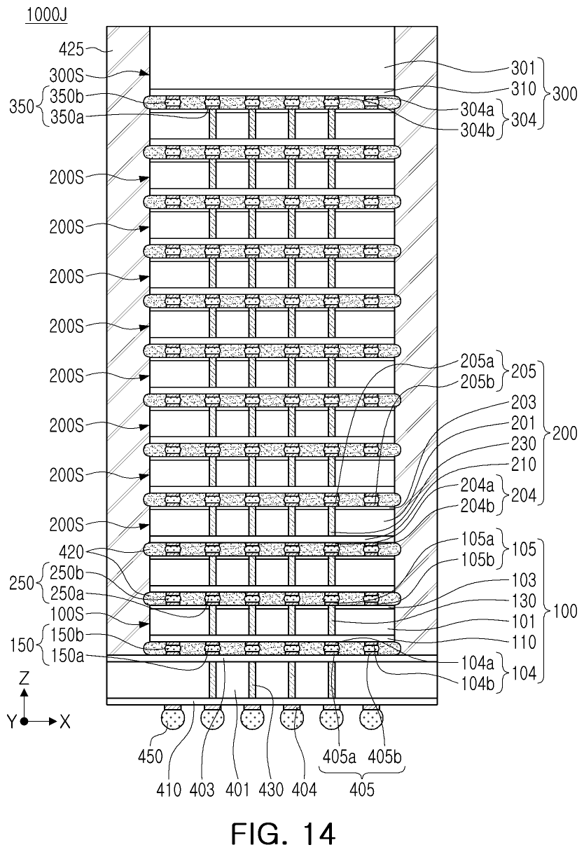

FIG. 14 is a cross-sectional view of a semiconductor package taken along line I-I of FIG. 1.

Referring to FIG. 14, a semiconductor package 1000J may be the same as or similar to that described with reference to FIGS. 1 to 13, except that the semiconductor package 1000J includes a plurality of second semiconductor chips 200 having a predetermined number.

The plurality of second semiconductor chips 200 may include ten vertically stacked semiconductor chips. In another aspect, the semiconductor package 1000J may include a total of twelve vertically stacked semiconductor chips 100, 200 and 300 on the base chip 400.

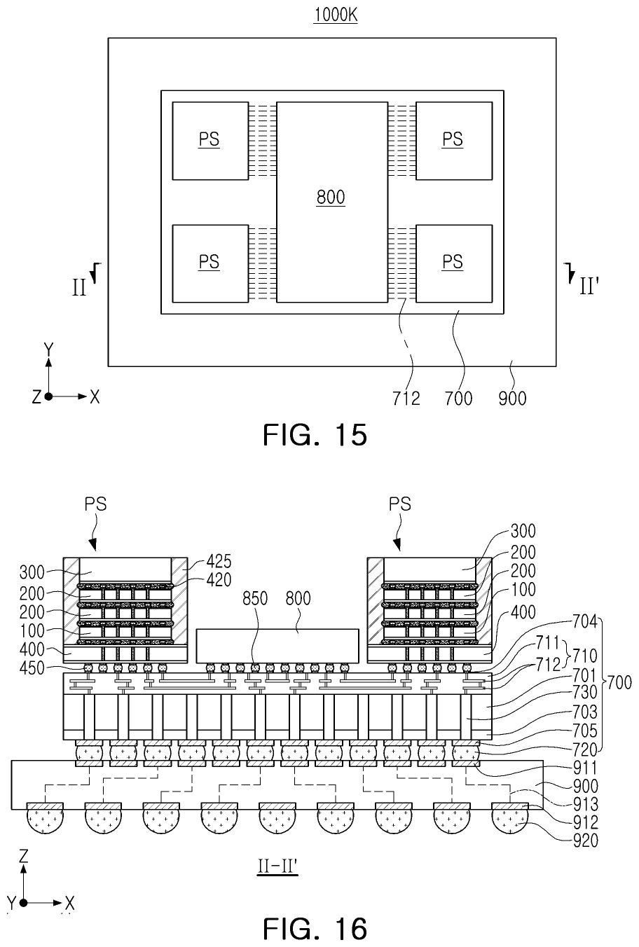

FIG. 15 is a plan view illustrating a semiconductor package according to an example embodiment.

FIG. 16 is a cross-sectional view illustrating a semiconductor package along II-II′ of FIG. 15.

Referring to FIGS. 15 and 16, a semiconductor package 1000K may include a package substrate 900, an interposer substrate 700, at least one chip structure PS, and a processor chip 800. The chip structure PS may have characteristics identical to or similar to the semiconductor packages 1000, 1000′, 1000A, 1000B, 1000C, 1000D, 1000E, 1000F, 1000G, 1000H, 1000I and 1000J described with reference to FIGS. 1 to 14.

The package substrate 900 is a support substrate on which the interposer substrate 700, the processor chip 800, and the chip structure PS are mounted, and may be a semiconductor package substrate including a printed circuit board (PCB), a ceramic substrate, a glass substrate and a tape interconnection substrate. A body of the package substrate 900 may include different materials depending on the type of the substrate. For example, when the package substrate 900 is a printed circuit board, the package substrate 900 may be in a form in which an interconnection layer is additionally stacked on one side or both sides of a body copper foil laminate or a copper foil laminate.

The package substrate 900 may include a lower terminal 912, an upper terminal 911, and an interconnection circuit 913. The upper terminal 911, the lower terminal 912, and the interconnection circuit 913 may form an electrical path for connecting a lower surface and an upper surface of the package substrate 900. The upper terminal 911, the lower terminal 912, and the interconnection circuit 913 may include a metallic material, and may include, for example, at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) or carbon (C), or alloys including two or more metals thereof. An external connection terminal 920 connected to the lower terminal 912 may be disposed on a lower surface of the package substrate 900. The external connection terminal 920 may include tin (Sn), indium (In), bismuth (Bi), antimony (Sb), copper (Cu), silver (Ag), zinc (Zn), lead (Pb), and/or alloys thereof.

The interposer substrate 700 may include a substrate 701, a lower protection layer 703, a lower pad 705, an interconnect structure 710, a metal bump 720, and a through-via 730. The chip structure PS and the processor chip 800 may be electrically connected to each other via the interposer substrate 700.

The substrate 701 may be formed of, for example, any one of a silicon, an organic, a plastic, and a glass substrate. When the substrate 701 is a silicon substrate, the interposer substrate 700 may be referred to as a silicon interposer. Unlike what is illustrated in the drawing, when the substrate 701 is an organic substrate, the interposer substrate 700 may be referred to as a panel interposer.

The lower protection layer 703 may be disposed on a lower surface of the substrate 701, and the lower pad 705 may be disposed below the lower protection layer 703. The lower pad 705 may be connected to the through-via 730. The chip structure PS and the processor chip 800 may be electrically connected to a package substrate 600 through the metal bumps 720 disposed below the lower pad 705.

The interconnect structure 710 may be disposed on an upper surface of the substrate 701 and may include an interlayer insulating layer 711 and a single-layer or multilayer interconnection structure 712. When the interconnect structure 710 is formed of a multilayer interconnection structure, interconnection patterns of different layers may be connected to each other through a contact via.

The through-via 730 may extend from the upper surface of the substrate 701 to the lower surface of the substrate 701 and may penetrate through the substrate 701. Additionally, the through-via 730 may extend into the interior of the interconnect structure 710 and may be electrically connected to interconnection lines of the interconnect structure 710. When the substrate 701 is silicon, the through-via 730 may be referred to as a through silicon via (TSV). According to an example embodiment, the interposer substrate 700 may only include an interconnect structure therein and might not include the through-via.

The interposer substrate 700 may be used for the purpose of converting or transmitting an input electrical signal between the package substrate 900 and the chip structure PS or the processor chip 800. Accordingly, the interposer substrate 700 may not include devices such as an active device or a passive device. Additionally, according to an example embodiment, the interconnect structure 710 may be disposed below the through-via 730. For example, a positional relationship between the interconnect structure 710 and the through-via 730 may be relative.

The metal bump 720 may electrically connect the interposer substrate 700 and the package substrate 900. The chip structure PS may be electrically connected to the metal bump 720 through the interconnect structure 710 and the through-via 730. According to an example embodiment, the lower pads 705 used for power or ground may be integrated and connected together to the metal bump 720, so that the number of the lower pads 705 may be greater than the number of the metal bumps 720.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, and an application-specific integrated circuit (ASIC). Connection bumps 850 may be disposed on a lower portion of the processor chip 800.

According to an example embodiment, a semiconductor package 1000K may further include an inner encapsulant covering the chip structure PS and the processor chip 800 on the interposer substrate 700. Additionally, the semiconductor package 1000K may further include an outer encapsulant covering the interposer substrate 700 and the inner encapsulant on the package substrate 900. The outer encapsulant and the inner encapsulant may be formed together and might not be distinguished from each other. According to an example embodiment, the semiconductor package 1000K may further include a heat dissipation structure covering the chip structure PS and the processor chip 800.

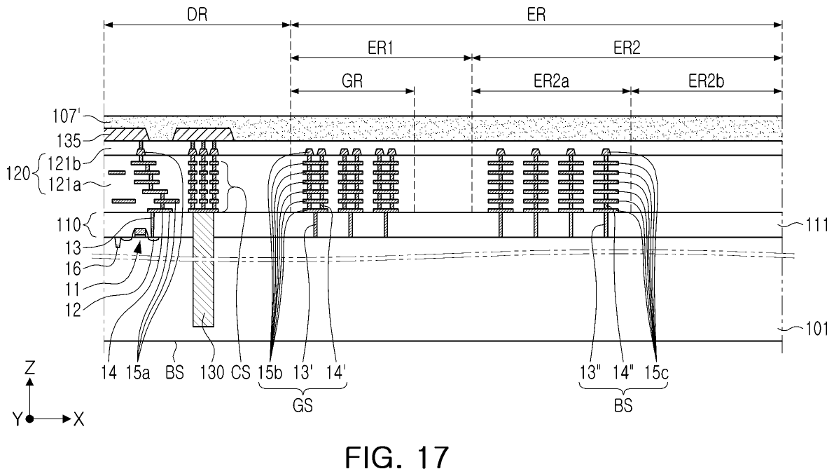

FIGS. 17 to 23 are cross-sectional views illustrating a method of manufacturing a semiconductor package according to an example embodiment of the present disclosure according to a process order.

Referring to FIG. 17, a substrate 101, a device layer 110 on the substrate 101, a through-via 130 penetrating through at least a portion of the substrate 101 and the device layer 110, an interconnection layer 120 on the device layer 110, an upper conductive pattern 135 on the interconnection layer 120, and a preliminary front protection layer 107′ covering the upper conductive pattern 135 on the interconnection layer 120 may be formed.

The device layer 110 may be formed on the substrate 101. Integrated circuit devices 11, a conductive region 12, and a separation region 16 may be formed in a device region DR on the substrate 101, and a lower insulating layer 111 covering the integrated circuit devices 11 may be formed on the substrate 101. The lower insulating layer 111 may include silicon oxide, silicon nitride, silicon oxynitride, or combinations thereof. Then, an interconnection portion 13 penetrating through the lower insulating layer 111 and the through-via 130 penetrating through at least a portion of the lower insulating layer 111 and the substrate 101 may be formed in the device region DR. A plurality of dummy connection layers 13′ and 13″ penetrating through the lower insulating layer 111 may be formed in the edge region ER. A region in which the dummy connection layers 13′ are formed may be defined as a first edge region ER1, and a region in which the dummy connection layers 13″ are formed may be defined as a second edge region ER2.

The interconnection layer 120 may be formed on the device layer 110. An interlayer insulating layer 121a covering a plurality of conductive patterns 15a, 15b and 15c including an uppermost conductive pattern may be formed on the device layer 110, and an upper insulating layer 121b covering an uppermost conductive pattern may be formed on the interlayer insulating layer 121a. Interconnection patterns 15a may be formed on the interconnection portion 13 and the through-via 130 on the device region DR, and guard ring patterns 15b may be formed on the dummy connection layers 13′ on the first edge region ER1, and blocking patterns 15c may be formed on the dummy connection layers 13″ on the second edge region ER2. Accordingly, the interconnection structure CS on the device region DR may be defined, the guard ring structure GS on the first edge region ER1 may be defined, and the crack blocking structure BS on the second edge region ER2 may be defined. Here, a region in which the guard ring structure GS is formed may be defined as a guard ring region GR, and a region in which the crack blocking structure BS is formed may be defined as a first region ER2a. A region other than the first region ER2a in the second edge region ER2 may be defined as a second region ER2b. Then, a conductive via penetrating the upper insulating layer 121b and connected to the uppermost conductive pattern may be formed.

The upper conductive pattern 135 may be formed on the interconnection layer 120. The upper conductive pattern 135 may be formed on the conductive via on the device region DR.

The preliminary front protection layer 107′ may be formed on the interconnection layer 120. The preliminary front protection layer 107′ may cover the interconnection structure CS and the upper conductive pattern 135 on the device region DR, and may cover the guard ring structure GS and the crack blocking structure BS of the edge region ER.

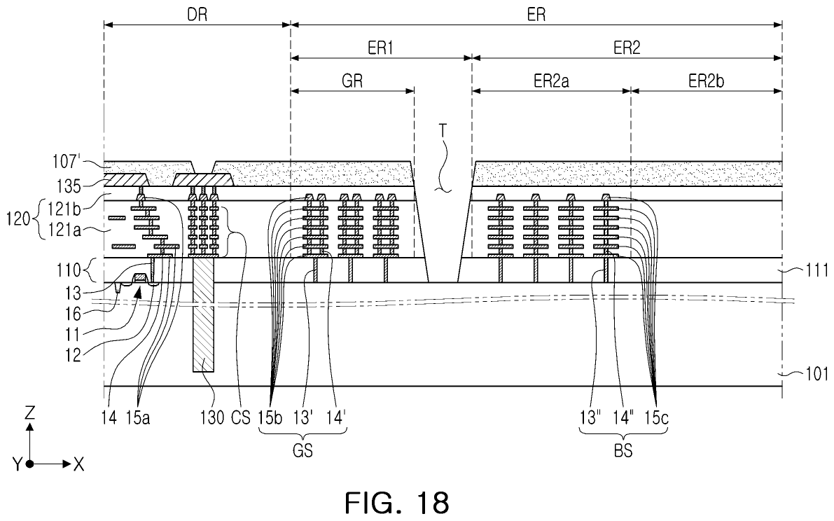

Referring to FIG. 18, a trench T penetrating through the preliminary front protection layer 107′, the interconnection layer 120 and the device layer 110 and exposing the substrate 101 may be formed between the guard ring structure GS and the crack blocking structure BS.

The trench T may be formed to surround the device region DR between the guard ring region GR of the first edge region ER1 and the first region ER2a of the second edge region ER2. The trench T may be formed to continuously surround the device region DR (see FIG. 3C). The trench T may be formed to discontinuously surround the device region DR (see FIG. 4).

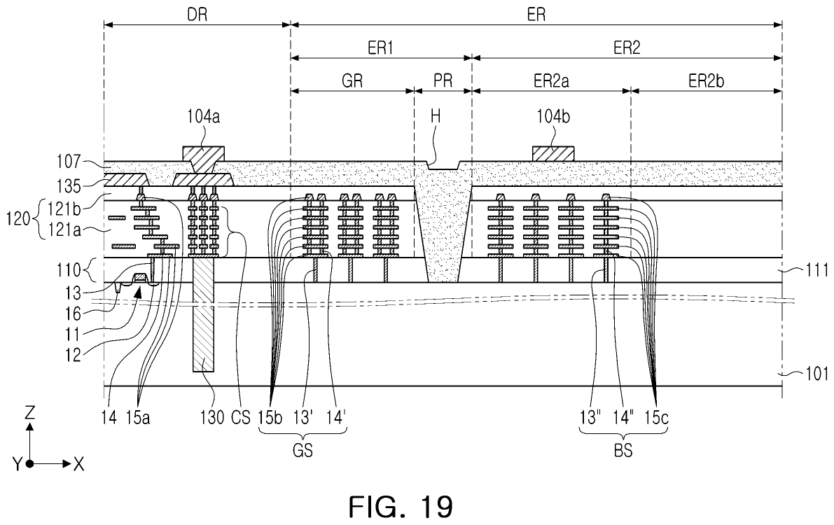

Referring to FIG. 19, an insulating material may be filled in the trench T to form a front protection layer 107. A first-first front pad 104a on the device region DR and a first-second front pad 104b on the edge region ER may be formed.

The insulating material may be filled in the trench T to form the front protection layer 107 having the horizontal portion (‘107h’ in FIG. 3B) and the protrusion portion (‘107p’ in FIG. 3B) extending in the vertical direction from the horizontal portion. A groove portion H may be formed on the protrusion portion.

On the device region DR, a hole exposing the upper conductive pattern 135 by penetrating through the front protection layer 107 may be formed, and the hole may be filled with a conductive material to form the first-first front pad 104a having a via portion and a pad portion.

On the first region ER2a of the second edge region ER2, the first-second front pad 104b may be formed (see FIG. 3A). The first-second front pad 104b may be formed in the second region ER2b (see FIG. 5A). The first-second front pad 104b may be formed so that the end (‘104_EP’ in FIG. 6B) of the first-second front pad 104b may be aligned with a portion in which the horizontal portion (‘107h’ in FIG. 6B) of the front protection layer 107 and the protrusion portion (‘107p’ in FIG. 6) meet each other (see FIG. 6). The first-second front pad 104b may be formed so that the end of the first-second front pad 104b may be aligned with the side surface 1005 of the semiconductor chip 100 formed through a vertical cutting process (see FIG. 7A). The first-second front pad 104b may be formed to have the horizontal portion (‘104b_p’ in FIG. 8) and the via portion (104b_v in FIG. 8) extending in the vertical direction from the horizontal portion (see FIG. 8). The first-second front pad 104b may be formed to have a maximum width greater than a maximum width of the first-first front pad 104a in the horizontal direction (see FIG. 9). The first-second front pad 104b may be formed in plural so that the outer side of the device region DR may be surrounded with a plurality of layers (see FIG. 10). The first-second front pad 104b may not be formed (see FIG. 13).

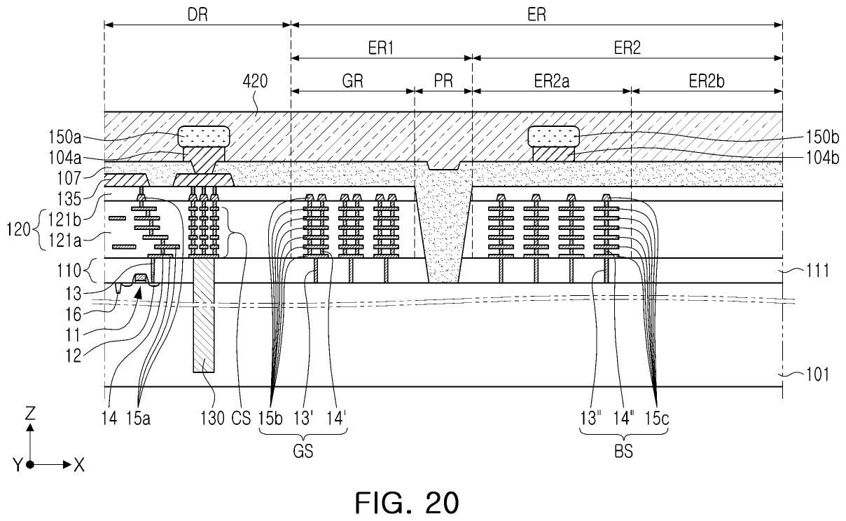

Referring to FIG. 20, connection bumps 150 may be formed on the front pads 104. An adhesive layer 420 surrounding the front pads 104 and the connection bumps 150 may be formed.

A first-first connection bump 150a may be formed on the first-first front pad 104a on the device region DR, and a first-second connection bump 150b may be formed on the first-second front pad 104a on the first region ER2a of the second edge region ER2. According to an example embodiment, the first-second connection bump 150b may not be formed (see FIGS. 11 to 13). Then, an adhesive layer 420 surrounding the front pads 104 and the connection bumps 150 may be formed on the device region DR and the edge region ER.

The adhesive layer 420 may have the horizontal portion (‘420h’ of FIG. 3B) and the protrusion portion (‘420p’ of FIG. 3B) extending in the vertical direction from the horizontal portion. The protrusion portion may be a portion introduced into the groove portion (‘H’ of FIG. 18) formed in an upper region of the front protection layer 104.

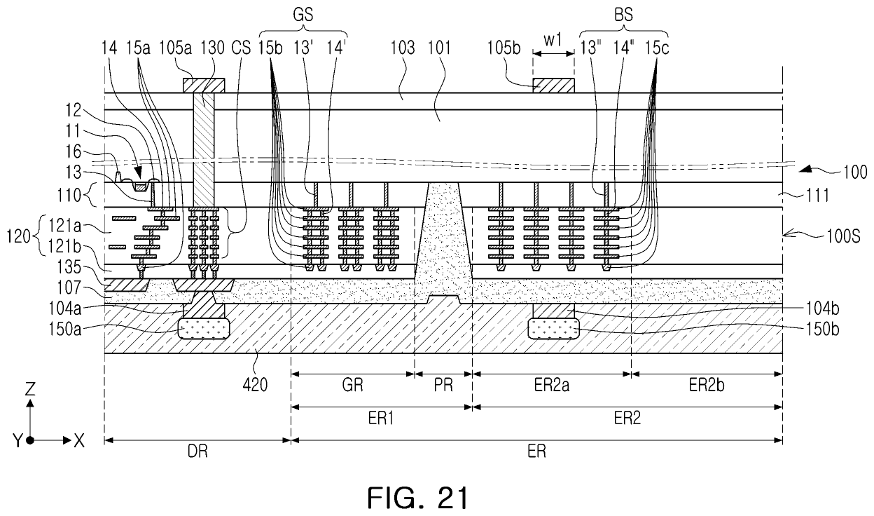

Referring to FIG. 21, a rear protection layer 103 covering a rear surface of the substrate 101 and surrounding the through-via 130 may be formed. Rear pads 105 may be formed on the rear protection layer 103.

The substrate 101 may be provided so that a rear surface BS thereof may be made to face up. The substrate 101 may be removed to expose the through-via 130. Then, the rear protection layer 103 covering the rear surface of the substrate 101 and surrounding the through-via 130 may be formed.

A first-first rear pad 105a in contact with the through-via 130 may be formed on the device region DR, and a first-second rear pad 105b may be formed on the first region ER2a of the second edge region ER2. According to an example embodiment, the first-second rear pad 105b may not be formed (see FIG. 12).

Then, the first semiconductor chip 100 having the side surface 100S may be formed by performing a cutting operation using a blade in the vertical direction.

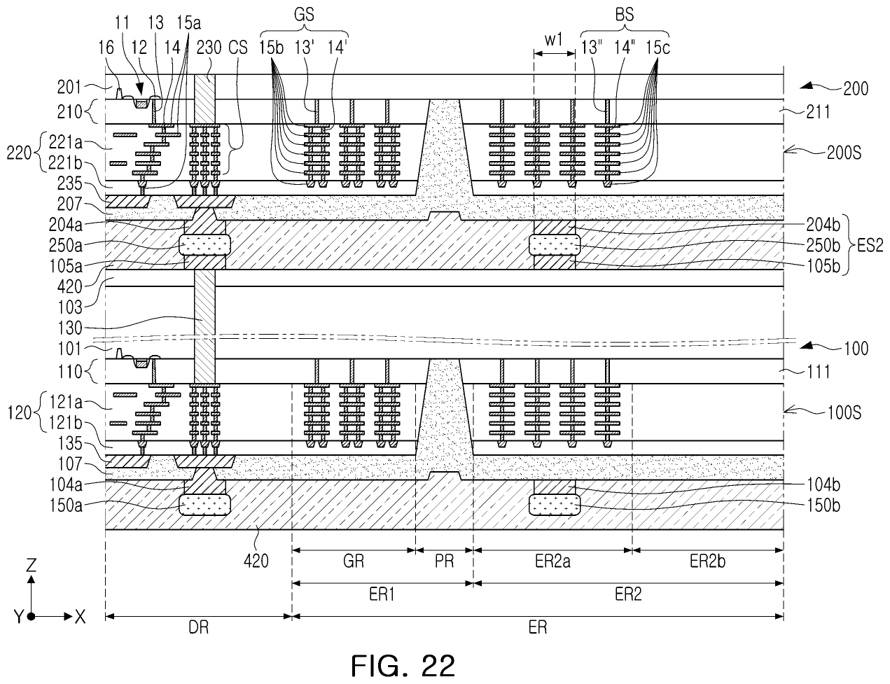

Referring to FIG. 22, the second semiconductor chip 200 may be formed on the first semiconductor chip 100.

The second semiconductor chip 200 may be formed through substantially the same process as that of the first semiconductor chip 100 described with reference to FIGS. 16 to 20.

The second semiconductor chip 200 may be formed on the first semiconductor chip 100. The second semiconductor chip 200 may be formed on the first semiconductor chip 100 so that the adhesive layer 420 disposed therebelow may come into contact with the rear protection layer 103 and the rear pads 105 of the first semiconductor chip 100. A plurality of second semiconductor chips 200 may be sequentially stacked on the first semiconductor chip 100.

Accordingly, the third semiconductor chip (‘300’ in FIG. 2) may be formed on the second semiconductor chip 200 on an uppermost side.

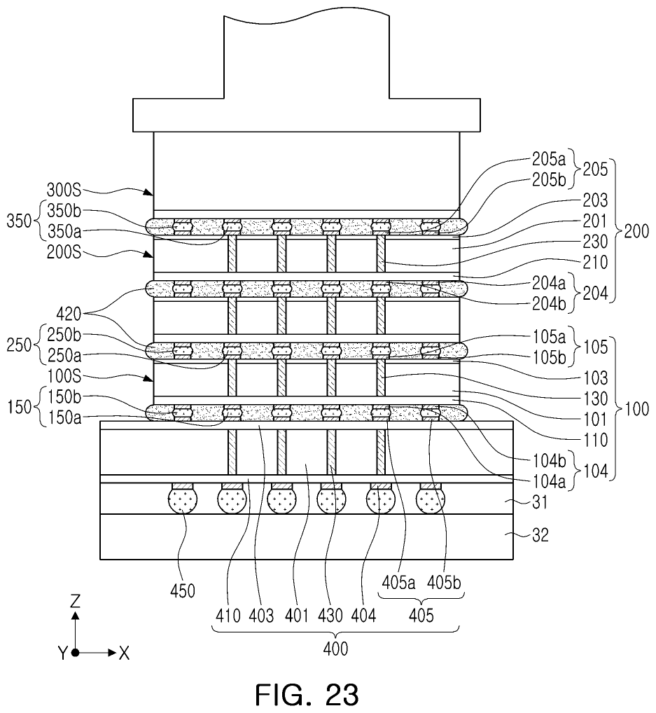

Referring to FIG. 23, a plurality of semiconductor chips 100, 200 and 300 may be formed on a base chip 400. The plurality of semiconductor chips 100, 200 and 300 may be conveniently referred to as a chip stack.

The base chip 400 temporarily attached to a carrier substrate 32 by a bonding material layer 31 may be provided. The base chip 400 may include a substrate 401, a device layer 410, an upper protection layer 403, through-electrodes 430 penetrating through the substrate 401 and the upper protection layer 403, upper pads 405 having first-first and first-second upper pads 405a and 405b, and lower pads 405 and 404. The adhesive material layer 31 may be provided to surround connection bumps 450 on the lower surface of the base chip 400.

The chip stack may be picked and disposed on the base chip 400 and may then be subject to thermal compression bonding. The first-first connection bumps 150a may be in contact with the first-first upper pads 405a, and the first-second connection bumps 105b may be in contact with the first-second upper pads 405b. By thermal compression bonding, the adhesive layers 420 may have fillet portions protruding further outward than the side surfaces 100S, 200S and 300S of the semiconductor chips 100, 200, and 300.

Then, the bonding material layer 31 and the carrier substrate 32 may be removed, thereby providing the semiconductor package 1000.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor package, comprising:
a base chip comprising upper pads on an upper surface of the base chip;
a first semiconductor chip on the base chip, and the first semiconductor chip comprising a first semiconductor substrate, first rear pads disposed on a rear surface thereof, and first front pads disposed on a front surface thereof;
one or more second semiconductor chips stacked on the first semiconductor chip, and respectively comprising a second semiconductor substrate, second rear pads disposed on a rear surface thereof, and second front pads disposed on a front surface thereof, wherein each of the first and second semiconductor substrates comprises a device region and an edge region surrounding the device region, and the upper pads, the first and second rear pads and the first and second front pads overlap the device region;
first connection bumps overlapping the device region and disposed on a lower portion of the first semiconductor chip, and electrically connecting the first front pads of the first semiconductor chip and the upper pads of the base chip;
a first edge structure overlapping the edge region and disposed on the lower portion of the first semiconductor chip;
second connection bumps overlapping the device region and disposed on a lower portion of each of the one or more second semiconductor chips, and electrically connecting pads facing each other among the first rear pads, the second front pads, and the second rear pads;
a second edge structure overlapping the edge region and disposed on the lower portion of each of the one or more second semiconductor chips;
a first adhesive layer disposed on the front surface of the first semiconductor chip and surrounding the first connection bumps and the first edge structure; and
a second adhesive layer disposed on the front surface of each of the one or more second semiconductor chips and surrounding the second connection bumps and the second edge structure,
wherein each of the first and second edge structures comprises a material having a thermal expansion coefficient lower than a thermal expansion coefficient of the first adhesive layer and a thermal expansion coefficient of the second adhesive layer.

2. The semiconductor package of claim 1,
wherein each of the first and second edge structures comprises a conductive material, and each of the first and second adhesive layers comprises a non-conductive material.

3. The semiconductor package of claim 1,
wherein at least one of the first and second edge structures continuously surrounds an outer side of the device region.

4. The semiconductor package of claim 1,
wherein at least one of the first and second edge structures discontinuously surrounds an outer side of the device region.

5. The semiconductor package of claim 1,
wherein a maximum width of at least one of the first and second edge structures in a horizontal direction ranges from approximately 5 um to approximately 100 um.

6. The semiconductor package of claim 1,
wherein the edge region comprises:
a first edge region in which a guard ring structure surrounding the device region is disposed; and
a second edge region in which a crack blocking structure of an outer side of the guard ring structure is disposed, and which surrounds the first edge region, and
wherein each of the first and second edge structures overlaps the second edge region.

7. The semiconductor package of claim 6, further comprising:
a vertical insulating structure between the guard ring structure and the crack blocking structure,
wherein each of the first and second edge structures is disposed on an outer side of the vertical insulating structure,

8. The semiconductor package of claim 1,
wherein at least one of the first and second edge structures comprises a first inactive pad disposed on a lower surface of a corresponding semiconductor chip among the first semiconductor chip and the one or more second semiconductor chips or a second inactive pad disposed on an upper surface of a semiconductor chip among the one or more second semiconductor chips facing the lower surface of the corresponding semiconductor chip and facing the first inactive pad.

9. The semiconductor package of claim 8,
wherein the first inactive pad comprises:
a horizontal portion on the lower surface; and
a via portion extending in a vertical direction from an upper surface of the horizontal portion and disposed in a lower region of the corresponding semiconductor chip.

10. The semiconductor package of claim 1,
wherein at least one of the first and second edge structures comprises a first inactive pad disposed on a lower surface of a corresponding semiconductor chip among the first semiconductor chip and the one or more second semiconductor chips, and a second inactive pad disposed on an upper surface of a semiconductor chip among the one or more second semiconductor chips facing the lower surface of the corresponding semiconductor chip and facing the first inactive pad.

11. The semiconductor package of claim 1,
wherein at least one of the first and second edge structures comprises a first inactive pad disposed on a lower surface of a corresponding semiconductor chip among the first semiconductor chip and the one or more second semiconductor chips, a second inactive pad disposed on an upper surface of a semiconductor chip among the one or more second semiconductor chips facing the lower surface of the corresponding semiconductor chip and facing the first inactive pad, and a bump structure between the first and second inactive pads.

12. A semiconductor package, comprising:
a base chip;
a first semiconductor chip on the base chip, and the first semiconductor chip comprising a first semiconductor substrate and a first passivation layer on the first semiconductor substrate;
a second semiconductor chip on the first semiconductor chip, the second semiconductor chip comprising a second semiconductor substrate and a second passivation layer on the second semiconductor substrate;
wherein each of the first and second semiconductor substrates comprises:
a device region;
a first edge region surrounding the device region; and
a second edge region surrounding the first edge region;
a guard ring structure comprising a plurality of guard ring pattern layers stacked in a vertical direction on the first edge region;
a crack blocking structure comprising a plurality of blocking pattern layers stacked in the vertical direction on the second edge region;
first connection bumps overlapping the device region and disposed on a lower portion of the first passivation layer of the first semiconductor chip, and electrically connecting the base chip and the first semiconductor chip;
second connection bumps overlapping the device region and disposed on a lower portion of the second passivation layer of the second semiconductor chip, and electrically connecting the first and second semiconductor chips;
a first edge structure overlapping the second edge region and disposed on the lower portion of the first passivation layer of the first semiconductor chip;
a second edge structure overlapping the second edge region and disposed on the lower portion of the second passivation layer of the second semiconductor chip; and
adhesive layers comprising a first adhesive layer and a second adhesive layer, wherein the first adhesive layer at least partially surrounds the first connection bumps and the first edge structure on the first passivation layer, and the second adhesive layer at least partially surrounds the second connection bumps and the second edge structure on the second passivation layer.

13. The semiconductor package of claim 12,
wherein each of the first and second passivation layers comprises:
a first horizontal portion in which at least a portion thereof extends in a horizontal direction; and
a first protrusion portion protruding in the vertical direction between the guard ring structure and the crack blocking structure from an upper surface of the first horizontal portion.

14. The semiconductor package of claim 13,
wherein each of the first and second adhesive layers comprises:
a second horizontal portion extending in the horizontal direction; and
a second protrusion portion protruding from an upper surface of the second horizontal portion to a lower region of the first horizontal portion.

15. The semiconductor package of claim 13,
wherein the first protrusion portion of each of the first and second passivation layers comprises:
a first side facing a side surface of the first and second semiconductor chips; and
a second side opposite to the first side,
wherein an end of at least one of the first and second edge structures is aligned with a portion in which the first side of the first protrusion portion is in contact with the first horizontal portion.

16. The semiconductor package of claim 12,
wherein an end of the at least one of the first and second edge structures is aligned with a side surface of the corresponding first and second semiconductor chips.

17. The semiconductor package of claim 12,
wherein a horizontal width of at least one of the first and second edge structures is greater than a horizontal width of at least one of the first and second connection bumps.

18. The semiconductor package of claim 12,
wherein at least one of the first and second edge structures comprises:
a first structure continuously or discontinuously surrounding an outer side of the device region; and
a second structure continuously or discontinuously surrounding an outer side of the first structure.

19. A semiconductor package, comprising:
a base chip comprising first-first and first-second upper pads disposed on an upper surface thereof;
a first semiconductor chip disposed on the base chip, and comprising a first semiconductor substrate and a first passivation layer on the first semiconductor substrate, wherein the first semiconductor chip has first-first and first-second rear pads disposed on a first rear surface of the first semiconductor chip, and first-first and first-second front pads disposed on a first front surface of the first semiconductor chip;
one or more second semiconductor chips stacked on the first semiconductor chip, and respectively comprising a second semiconductor substrate and a second passivation layer on the second semiconductor substrate, wherein each of the one or more second semiconductor chips has second-first and second-second rear pads disposed on a second rear surface of the one or more second semiconductor chips, and second-first and second-second front pads disposed on a second front surface of the one or more second semiconductor chips,
wherein each of the first and second semiconductor substrates comprises:
a device region;
a first edge region surrounding the device region and having a guard ring structure disposed thereon; and
a second edge region surrounding the first edge region and having a crack blocking structure disposed therein,
the first-first upper pads, the first-first and second-first rear pads, and the first-first and second-first front pads overlap the device region, and
the first-second upper pads, the first-second and second-second rear pads, and the first-second and second-second front pads overlap the second edge region;
first-first connection bumps overlapping the device region in a lower portion of the first passivation layer of the first semiconductor chip, and electrically connecting the first-first upper pads and the first-first rear pads facing each other;
first-second connection bumps overlapping the second edge region and disposed on the lower portion of the first passivation layer of the first semiconductor chip, and connecting the first-second upper pads and the first-second rear pads facing each other;
second-first connection bumps overlapping the device region and disposed on a lower portion of the second passivation layer of the one or more second semiconductor chips, and connecting the first-first rear pads and the second-first front pads facing each other;
second-second connection bumps overlapping the second edge region and disposed on the lower portion of the second passivation layer of the one or more second semiconductor chips and connecting the first-second rear pads and the second-second front pads facing each other; and
adhesive layers comprising a first adhesive layer surrounding the first-first and first-second connection bumps on the first passivation layer, and a second adhesive layer surrounding the second-first and second-second connection bumps on the second passivation layer.

20. The semiconductor package of claim 19,
wherein each of the first and second passivation layers comprises:
a horizontal portion in which at least a portion thereof extends in a horizontal direction; and
a protrusion portion protruding in a vertical direction between the guard ring structure and the crack blocking structure from an upper surface of the horizontal portion.
